(19) United States
(12) Patent Application Publication
(10) Pub. No.: US 2025/0031371 A1
(43) Pub. Date: Jan. 23, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Nam Jae LEE, Gyeonggi-do (KR)

(21) Appl. No.: 18/470,428

(22) Filed: Sep. 20, 2023

(30) Foreign Application Priority Data
Jul. 20, 2023 (KR) 10-2023-0094529

(51) Int. Cl. H10B 43/27; H10B 41/27

(52) U.S. Cl. CPC H10B 43/27; H10B 41/27

(57) ABSTRACT

A semiconductor device may include a first gate structure including first gate lines each first gate line being exposed by a first step structure extending in a first direction, a second gate structure disposed on the first gate structure to expose the first step structure and including second gate lines each second gate line being exposed by a second step structure extending in the first direction, a channel structure extending through the first gate structure and the second gate structure, the channel structure having a first width, a first support extending through the first step structure, the first support having a second width that is greater than the first width, and a second support extending through the second step structure and the first gate structure, the second support having a third width that is greater than the first width.

### CROSS-REFERENCE TO RELATED APPLICATION

This application claims priority under 35 U.S.C. § 119 to Korean Patent Application No. 10-2023-0094529 filed on Jul. 20, 2023, which is incorporated herein by reference in its entirety.

### BACKGROUND

### 1. Technical Field

The present disclosure relates to an electronic device, and more particularly, to a semiconductor device and a method of manufacturing the semiconductor device.

### 2. Related Art

An integration degree of a semiconductor device is mainly determined by an area occupied by a unit memory cell. Recently, as improvement in the integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a first gate structure including first gate lines each first gate line being exposed by a first step structure extending in a first direction, a second gate structure disposed on the first gate structure to expose the first step structure and including second gate lines each second gate line being exposed by a second step structure extending in the first direction, a channel structure extending through the first gate structure and the second gate structure, the channel structure having a first width, a first support extending through the first step structure, the first support having a second width that is greater than the first width, and a second support extending through the second step structure and the first gate structure, the second support having a third width that is greater than the first width.

According to an embodiment of the present disclosure, a semiconductor device may include a first gate structure including first gate lines each exposed by a first step structure extending in a first direction, a second gate structure disposed on the first gate structure to expose the first step structure and including second gate lines each exposed by a second step structure extending in the first direction, an etch stop layer positioned between the first gate structure and the second gate structure to expose the first step structure, a channel structure extending through the first gate structure, the etch stop layer, and the second gate structure, and including a stepped sidewall, a first support extending through the first step structure and including a non-stepped sidewall, and a second support extending through the second step structure, the etch stop layer, and the first gate structure.

According to an embodiment of the present disclosure, a method of manufacturing a semiconductor device may include forming a first stack including a first cell region and a first contact region, forming an etch stop layer on the first stack, forming a second stack including a second cell region and a second contact region on the etch stop layer, forming a trench extending through the second stack and the etch stop layer and partially exposing the first contact region, and forming a first step structure positioned in the first stack and a second step structure positioned in the second stack, by patterning the first contact region and the second contact region in a step shape.

According to an embodiment of the present disclosure, a method of manufacturing a semiconductor device may include forming a first stack including first material layers, forming an etch stop layer on the first stack, forming a second stack including second material layers on the etch stop layer, exposing the etch stop layer by etching the second stack, exposing the first stack by etching the etch stop layer, forming a first step structure exposing each of the first material layers and a second step structure exposing each of the second material layers and the etch stop layer, by patterning the first stack and the second stack in a step shape, replacing the first material layers, the etch stop layer, and the second material layers with third material layers, and forming contact plugs connected to the third material layers, respectively.

### BRIEF DESCRIPTION OF THE DRAWINGS

FIGS. 1A to 1C are diagrams illustrating a structure of a semiconductor device according to an embodiment of the present disclosure.

FIGS. 2A to 2C are diagrams illustrating a structure of a semiconductor device according to an embodiment of the present disclosure.

FIGS. 3A to 3C are diagrams illustrating a structure of a semiconductor device according to an embodiment of the present disclosure.

FIGS. 4A to 10A, 4B to 10B, and 6C to 10C are diagrams illustrating a method of manufacturing a semiconductor device according to an embodiment of the present disclosure.

FIGS. 11A to 16A, 11B to 16B, and 11C to 16C are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and improved characteristic.

An integration degree of a semiconductor device may be improved by stacking memory cells in a three dimension. In addition, a semiconductor device having a stable structure and improved reliability may be provided.

Hereinafter, embodiments according to the technical spirit of the present disclosure are described with reference to the accompanying drawings.

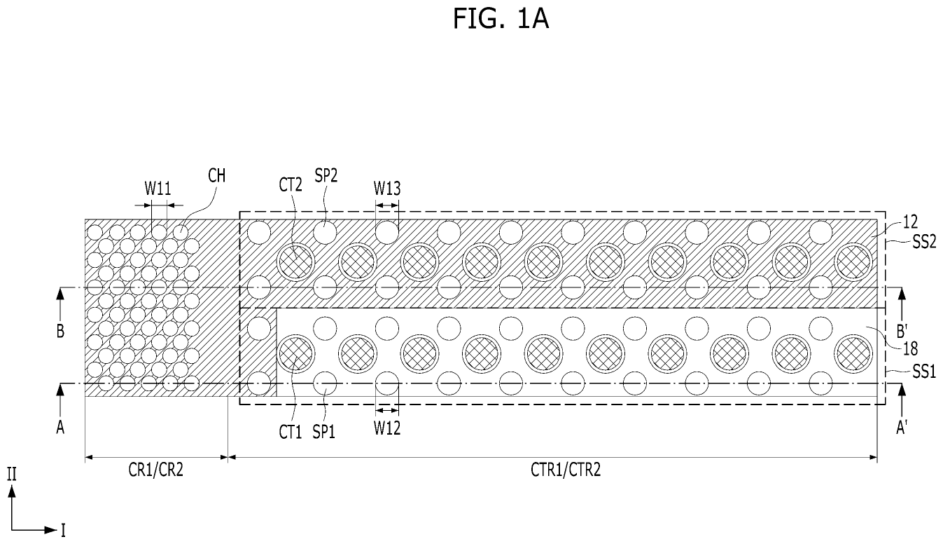

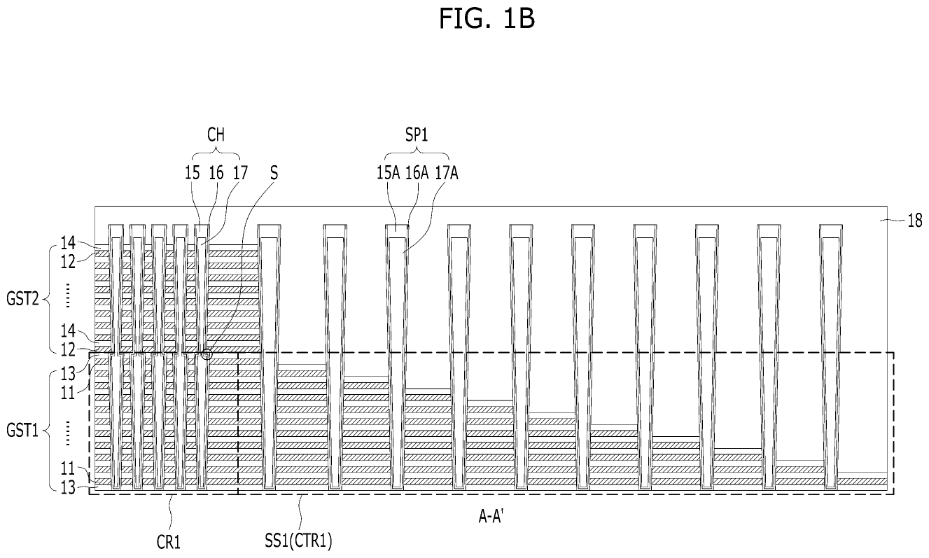

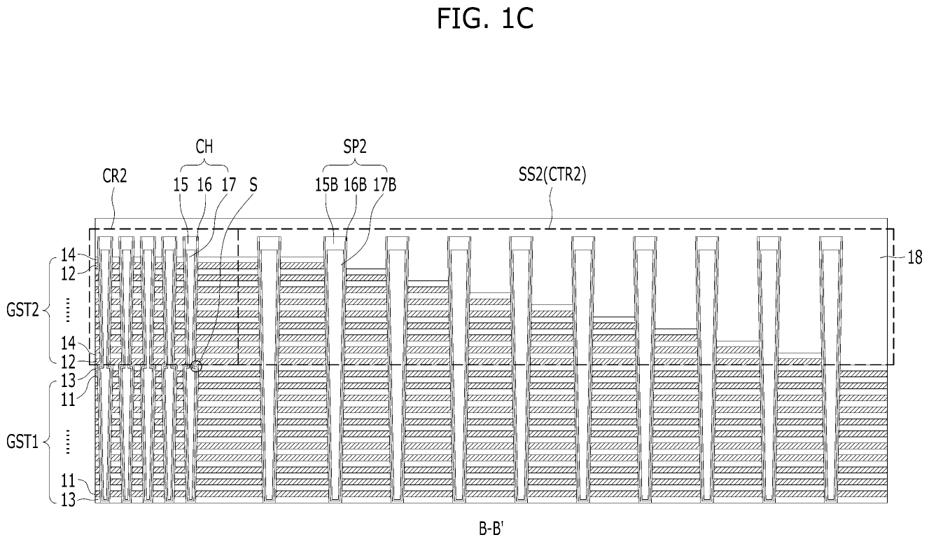

FIGS. 1A to 1C are diagrams illustrating a structure of a semiconductor device according to an embodiment of the present disclosure. FIG. 1A is a plan view, FIG. 1B is a cross-sectional view taken along a line A-A′ of FIG. 1A, and FIG. 1C is a cross-sectional view taken along a line B-B′ of FIG. 1A.

Referring to FIGS. 1A to 1C, the semiconductor device may include a first gate structure GST1, a second gate structure GST2, a channel structure CH, a first support SP1, and a second support SP2. The semiconductor device may further include at least one of an insulating layer 18, a first contact plug CT1, and a second contact plug CT2.

The first gate structure GST1 may include first gate lines 11. The first gate structure GST1 may include the first gate lines 11 and first insulating layers 13 that are alternately stacked. The first gate line 11 may be a select line or a word line, and may include a conductive material such as polysilicon or metal. The first insulating layers 13 may insulate the stacked first gate lines 11 from each other, and may include an insulating material such as oxide, nitride, an air gap, or a void.

The first gate structure GST1 may include a first cell region CR1 and a first contact region CTR1. The first cell region CR1 and the first contact region CTR1 may be adjacent to each other in a first direction I. The first gate structure GST1 may include a first step structure SS1 positioned in the first contact region CTR1. The first step structure SS1 may have a step shape extending in the first direction I, and each of the first gate lines 11 may be exposed by the first step structure SS1.

The second gate structure GST2 may be positioned on the first gate structure GST1 and may expose the first step structure SS1. The second gate structure GST may include second gate lines 12. The second gate structure GST2 may include the second gate lines 12 and second insulating layers 14 that are alternately stacked. The second gate line 12 may be a select line or a word line, and may include a conductive material such as polysilicon or metal. The second insulating layers 14 may insulate the stacked second gate lines 12 from each other, and may include an insulating material such as oxide, nitride, an air gap, or a void.

The second gate structure GST2 may include a second cell region CR2 and a second contact region CTR2. The second cell region CR2 and the second contact region CTR2 may be adjacent to each other in the first direction I. The first cell region CR1 and the second cell region CR2 may overlap in a stack direction, and the first contact region CTR1 and the second contact region CTR2 may overlap in a stack direction.

The second gate structure GST2 may include a second step structure SS2 positioned in the second contact region CTR2. The second step structure SS2 may have a step shape extending in the first direction I, and each of the second gate lines 12 may be exposed by the second step structure SS2. The first step structure SS1 and the second step structure SS2 may be adjacent to each other in a second direction II and may be mutually aligned in the second direction II. Here, the second direction II may be a direction crossing the first direction I. An insulating layer 18 may be positioned on the second gate structure GST2. The insulating layer 18 may cover the first step structure SS1 and the second step structure SS2.

The channel structure CH may extend through the first gate structure GST1 and the second gate structure GST2. The channel structure CH may extend through the first cell region CR1 of the first gate structure GST1 and the second cell region CR2 of the second gate structure GST2. The channel structure CH may include a channel layer 15, a memory layer 16, and an insulating core 17, or may include a combination thereof. The memory layer 16 may include at least one of a tunneling layer, a data storage layer, and a blocking layer, and the data storage layer may include a floating gate, polysilicon, a charge trap material, nitride, a variable resistance material, or the like.

The first support SP1 may extend through the first step structure SS1. The first support SP1 may pass through the insulating layer 18 and extend into the first step structure SS1. The second support SP2 may extend through the second step structure SS2 and the first gate structure GST1. The second support SP2 may pass through the insulating layer 18 and extend into the second step structure SS2.

The first support SP1 and the second support SP2 may have a shape similar to that of the channel structure CH. In an embodiment, the first support SP1 may include a first dummy channel layer 15A, a first dummy memory layer 16A, and a first dummy insulating core 17A, or may include a combination thereof. The second support SP2 may include a second dummy channel layer 15B, a second dummy memory layer 16B, and a second dummy insulating core 17B, or may include a combination thereof.

Sidewall shapes of the first support SP1, the second support SP2, and the channel structure CH may be similar to or different from each other. In an embodiment, the channel structure CH may be formed in an opening formed through a plurality of etching processes and may include a stepped sidewall. The stepped sidewall may include a step difference S positioned between the first gate structure GST1 and the second gate structure GST2. The first support SP1 and the second support SP2 may be formed in an opening formed through one etching process, and may include a non-stepped sidewall.

The first support SP1, the second support SP2, and the channel structure CH may have substantially the same width or different widths. The channel structure CH may have a first width W11, the first support SP1 may have a second width W12 greater than the first width W11, and the second support SP2 may have a third width W13 greater than the first width W11. In an embodiment, the second width W12 and the third width W13 may be greater than the first width W11, and the second width W12 and the third width W13 may be substantially the same. The width may be a width of an upper surface, a width of a lower surface, or an average width of a corresponding structure. The upper surface may be a top surface. The lower surface may be a bottom surface. In an embodiment, a width of an upper surface of the first support SP1 may be greater than a width of an upper surface of the channel structure CH, a width of an upper surface of the second support SP2 may be greater than the width of the upper surface of the channel structure CH. In the illustrated embodiments, the cross-sections of the channel structure CH, the first support SP1, and the second support SP2 may have a circle-shape and the width refers to the diameter of the cross-section. In other embodiments, (not shown), the cross-sections of the channel structure CH, the first support SP1, and the second support SP2 may have a square-shape and the width may refer to the diagonal of the square.

The first contact plugs CT1 may be positioned between the first supports SP1, and may be connected to the first gate lines 11, respectively. The second contact plugs CT2 may be positioned between the second supports SP2, and may be connected to the second gate lines 12, respectively. Each of the first contact plugs CT1 may be positioned centrally between four adjacent first supports SP1 positioned at the vertices of a square. Each of the second contact plugs CT2 may be positioned centrally between four adjacent second supports SP2 positioned at the vertices of a square.

According to the structure described above, the first step structure SS1 and the second step structure SS2 of the first gate structure GST1 may be adjacent to each other in the second direction II. The first step structure SS1 and the second step structure SS2 of the first gate structure GST1 may be in contact to each other. The first step structure SS1 and the second step structure SS2 may be formed through the same patterning process. First steps included in the first step structure SS1 and second steps included in the second step structure SS2 may be aligned in the second direction II. Therefore, the first step structure SS1 and the second step structure SS2 may be efficiently disposed, and a manufacturing process of the semiconductor device may be improved.

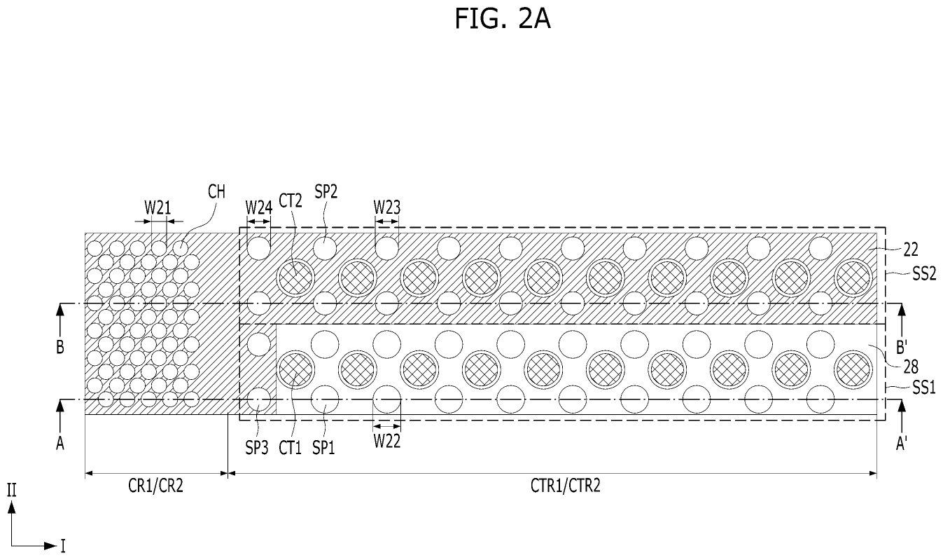

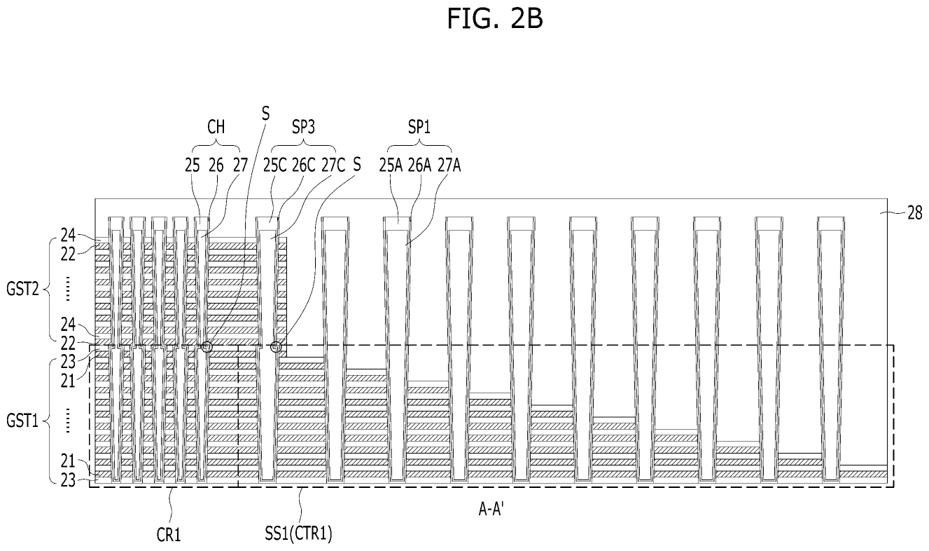

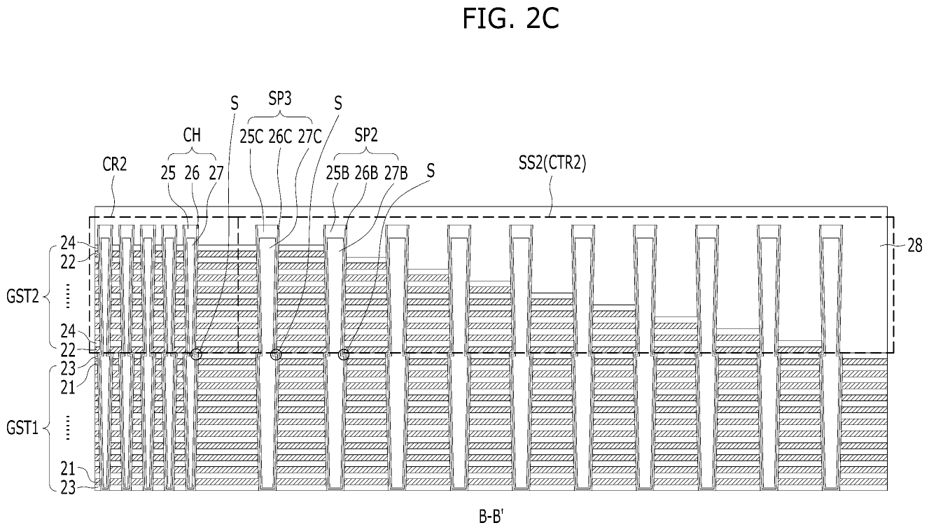

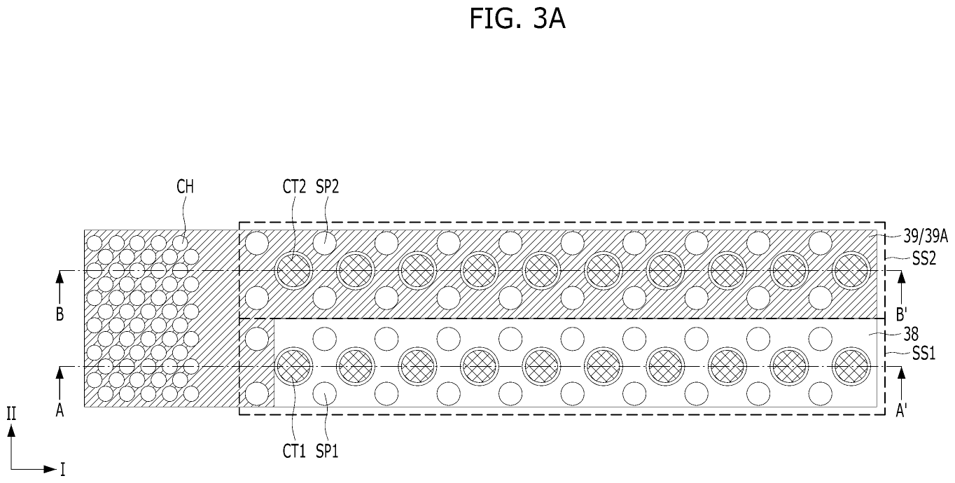

FIGS. 2A to 2C are diagrams illustrating a structure of a semiconductor device according to an embodiment of the present disclosure. FIG. 2A is a plan view, FIG. 2B is a cross-sectional view taken along a line A-A′ of FIG. 2A, and FIG. 2C is a cross-sectional view taken along a line B-B′ of FIG. 2A. Hereinafter, content overlapping the above-described content is omitted.

Referring to FIGS. 2A to 2C, the semiconductor device may include the first gate structure GST1, the second gate structure GST2, the channel structure CH, the first support SP1, and the second support SP2. The semiconductor device may further include at least one of an insulating layer 28, a third support SP3, the first contact plug CT1, and the second contact plug CT2.

The first gate structure GST1 may include first gate lines 21 and first insulating layers 23 that are alternately stacked. The first gate structure GST1 may include the first step structure SS1. The second gate structure GST2 may include second gate lines 22 and second insulating layers 24 that are alternately stacked. The second gate structure GST2 may include the second step structure SS2.

The channel structure CH may extend through the first gate structure GST1 and the second gate structure GST2. The channel structure CH may include a channel layer 25, a memory layer 26, and an insulating core 27, or may include a combination thereof. The first support SP1 may extend through the first step structure SS1. The first support SP1 may include a first dummy channel layer 25A, a first dummy memory layer 26A, and a first dummy insulating core 27A, or may include a combination thereof. The second support SP2 may extend through the second step structure SS2 and the first gate structure GST1. The second support SP2 may include a second dummy channel layer 25B, a second dummy memory layer 26B, and a second dummy insulating core 27B, or may include a combination thereof.

The third support SP3 may be positioned in the cell regions CR1/CR2 or in the contact regions CTR1/CTR2. The third support SP3 may be positioned between the channel structure CH and the first support SP1 or may be positioned between the channel structure CH and the second support SP2. The third support SP3 may extend through the second gate structure GST2 and the first gate structure GST1. The third support SP3 may have a shape similar to that of the channel structure CH. In an embodiment, the third support SP3 may include a third dummy channel layer 25C, a third dummy memory layer 26C, and a third dummy insulating core 27C, or may include a combination thereof.

Side wall shapes of the first support SP1, the second support SP2, and the third support SP3 may be similar to or different from each other. At least one of the first support SP1, the second support SP2, and the third support SP3 may include a stepped sidewall. In an embodiment, the second support SP2 and the third support SP3 may include a stepped sidewall, and the first support SP1 may include a non-stepped sidewall.

The first support SP1, the second support SP2, and the third support SP3 may have substantially the same width or different widths. The channel structure CH may have a first width W21. The second support SP2 may have a third width W23 greater than the first width W21. The first support SP1 may have a second width W22 greater than the first width W21 and the third width W23. The third support SP3 may have a fourth width W24 greater than the first width W21 and less than the second width W22. The fourth width W24 may be substantially the same as the third width W23.

The first contact plugs CT1 may be positioned between the first supports SP1 or may be positioned between the first support SP1 and the third support SP3. The second contact plugs CT2 may be positioned between the second supports SP2 or may be positioned between the second support SP2 and the third support SP3.

According to the structure as described above, the first step structure SS1 and the second step structure SS2 may be efficiently disposed, and the manufacturing process of the semiconductor device may be improved.

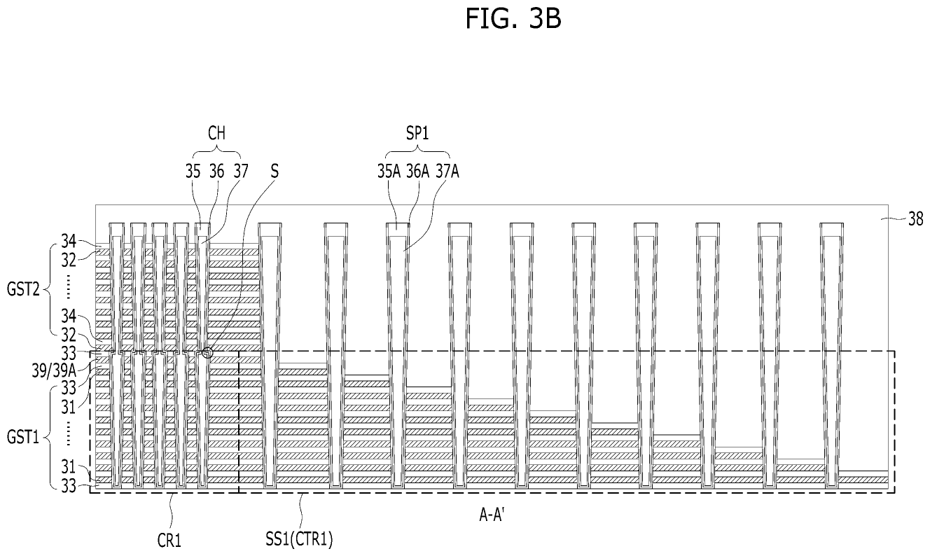

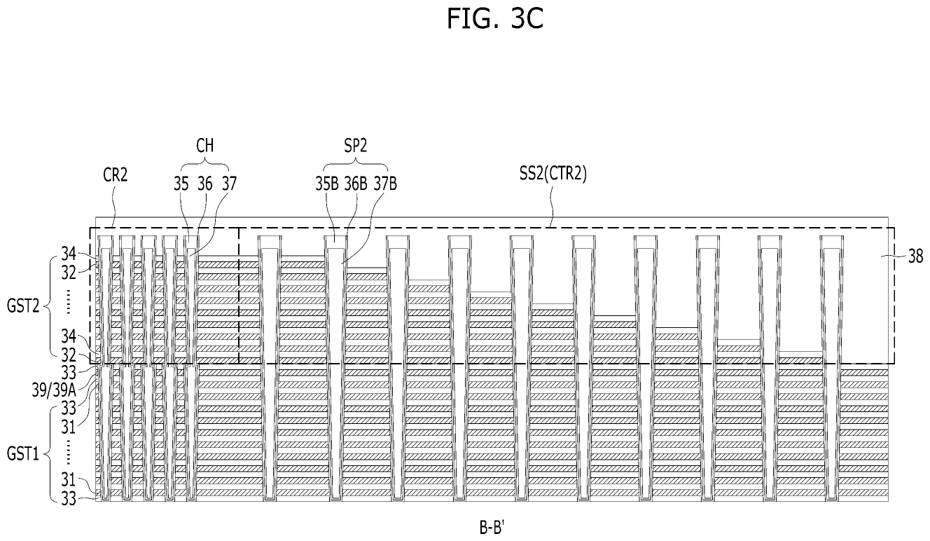

FIGS. 3A to 3C are diagrams illustrating a structure of a semiconductor device according to an embodiment of the present disclosure. FIG. 3A is a plan view, FIG. 3B is a cross-sectional view taken along a line A-A′ of FIG. 3A, and FIG. 3C is a cross-sectional view taken along a line B-B′ of FIG. 3A. Hereinafter, content overlapping the above-described content is omitted.

Referring to FIGS. 3A to 3C, the semiconductor device may include the first gate structure GST1, the second gate structure GST2, the channel structure CH, the first support SP1, and the second support SP2. The semiconductor device may further include at least one of an insulating layer 38, the first contact plug CT1, the second contact plug CT2, and an etch stop layer 39.

The first gate structure GST1 may include first gate lines 31 and first insulating layers 33 that are alternately stacked. The first gate structure GST1 may include the first step structure SS1. The second gate structure GST2 may include second gate lines 32 and second insulating layers 34 that are alternately stacked. The second gate structure GST2 may include the second step structure SS2.

The etch stop layer 39 may be positioned between the first gate structure GST1 and the second gate structure GST2. The etch stop layer 39 may be used as an etch barrier when etching a stack in a manufacturing process. The etch stop layer 39 may include a material having an etch selectivity with respect to the stack. In an embodiment, the etch stop layer 39 may include aluminum oxide (Al₂O₃), polysilicon, or the like.

The channel structure CH may extend through the first gate structure GST1, the etch stop layer 39, and the second gate structure GST2. The channel structure CH may include a channel layer 35, a memory layer 36, and an insulating core 37, or may include a combination thereof. The first support SP1 may extend through the first step structure SS1. The second support SP2 may extend through the second step structure SS2, the etch stop layer 39, and the first gate structure GST1. The first support SP1, the second support SP2, and the channel structure CH may have substantially the same width or different widths.

For reference, during a manufacturing process, the etch stop layer 39 may be replaced with a third gate line 39A, and the third gate line 39A may be included in the first gate structure GST1. The third gate line 39A may include the same material as the first gate line 31 and the second gate line 32 or may include a material different from a material of the first gate line 31 and the second gate line 32. In an embodiment, the first gate line 31, the second gate line 32, and the third gate line 39A may include a metal such as tungsten (W) or molybdenum (Mo). In an embodiment, the first gate line 31 and the second gate line 32 may include polysilicon, and the third gate line 39A may include a metal such as tungsten (W) or molybdenum (Mo). At least one of the second contact plugs CT2 may be electrically connected to the third gate line 39A.

As described above with reference to FIGS. 1A to 1C and 2A to 2C, the semiconductor device may further include the third support SP3. Side wall shapes of the first support SP1, the second support SP2, and the third support SP3 may be similar to or different from each other. The first support SP1, the second support SP2, and the third support SP3 may have substantially the same width or different widths.

The first contact plugs CT1 may be positioned between the first supports SP1 or may be positioned between the first support SP1 and the third support SP3. The second contact plugs CT2 may be positioned between the second supports SP2 or may be positioned between the second support SP2 and the third support SP3.

According to the structure as described above, the first step structure SS1 and the second step structure SS2 may be efficiently disposed, and the manufacturing process of the semiconductor device may be improved.

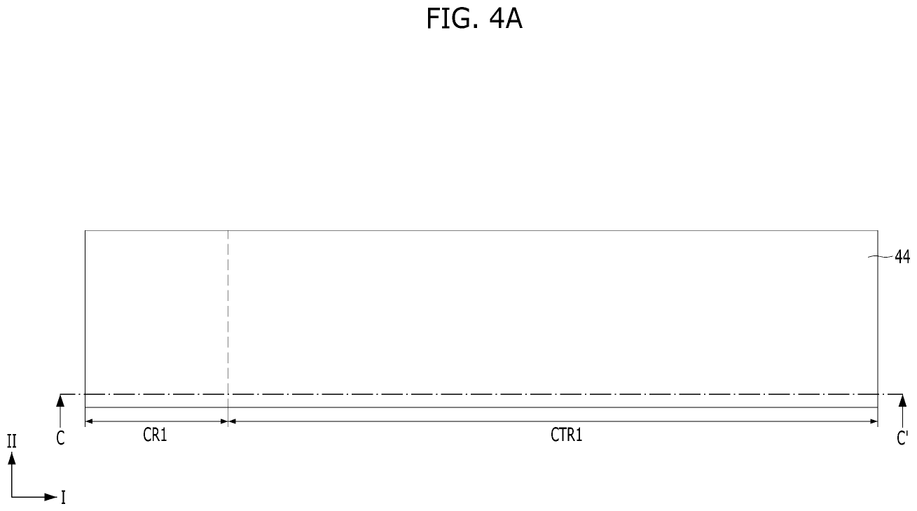

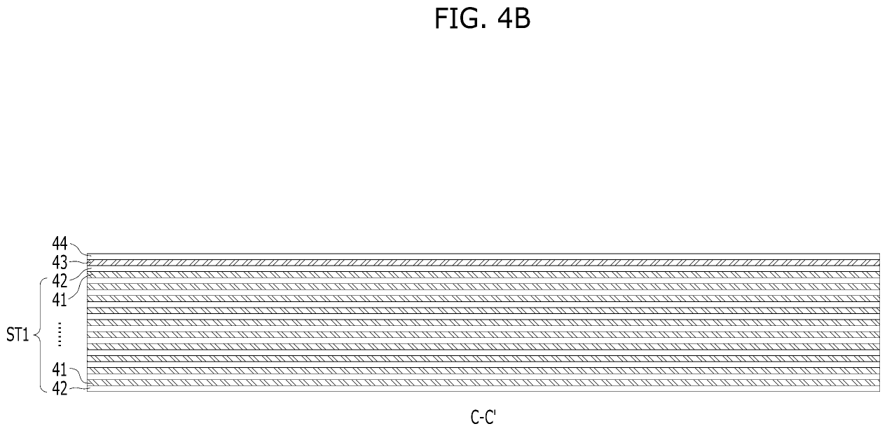

FIGS. 4A to 10A, 4B to 10B, and 6C to 10C are diagrams illustrating a method of manufacturing a semiconductor device according to an embodiment of the present disclosure. FIG. A of each FIG. is a plan view, FIG. B of each number is a C-C′ cross-sectional view of FIG. A, and FIG. C of each number is a D-D′ cross-sectional view of FIG. A. Hereinafter, content overlapping the above-described content is omitted.

Referring to FIGS. 4A and 4B, a first stack ST1 including the first cell region CR1 and the first contact region CTR1 may be formed. The first cell region CR1 may be a region in which stacked memory cells are formed. The first contact region CTR1 may be a region in which an interconnection structure for applying a bias to each of stacked gate lines is formed. The interconnection structure may include a contact plug, a line, and the like.

The first stack ST1 may include first material layers 41. In an embodiment, the first stack ST1 may include the first material layers 41 and first insulating layers 42 that are alternately stacked. The first material layers 41 may be for forming a gate line such as a select line or a word line. The first material layers 41 may include a sacrificial material such as nitride or may include a conductive material such as polysilicon or tungsten. The first insulating layer 42 may insulate the stacked gate lines from each other. The first insulating layer 42 may include an insulating material such as oxide, nitride, an air gap, or a void.

Subsequently, the etch stop layer 43 may be formed on the first stack ST1. The etch stop layer 43 may control an etching depth when a second stack is etched in a subsequent process. The etch stop layer 43 may include a material having a great etch selectivity with respect to the second stack. In an embodiment, the etch stop layer 43 may include at least one of aluminum oxide (Al₂O₃) and polysilicon. Subsequently, an insulating layer 44 may be formed on the etch stop layer 43. For reference, the etch stop layers 43 and the insulating layers 44 may be alternately stacked.

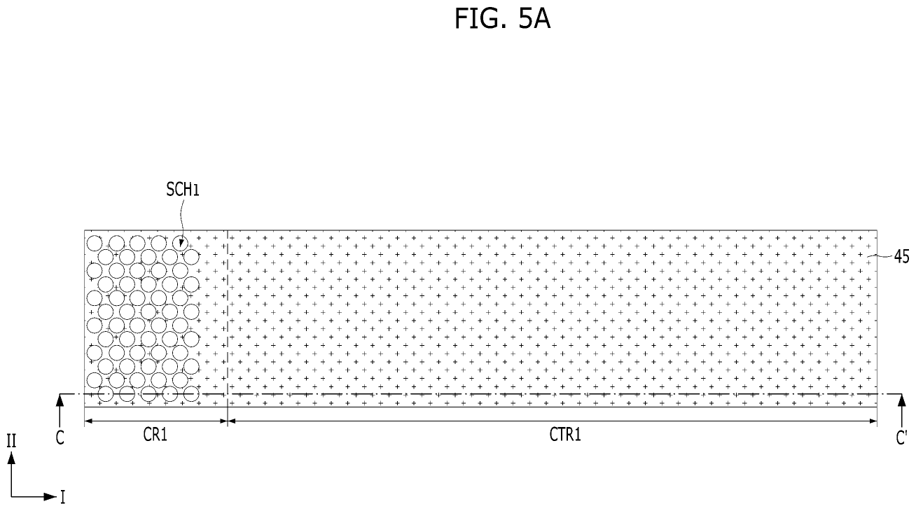

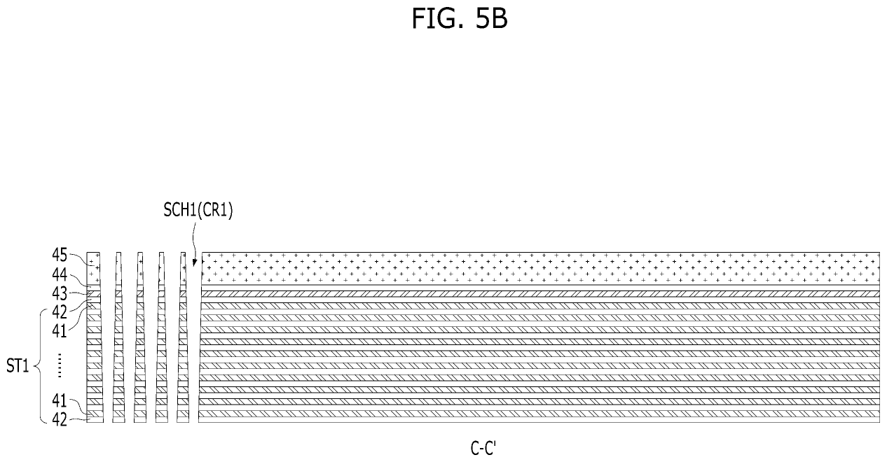

Referring to FIGS. 5A and 5B, a first mask pattern 45 may be formed on the etch stop layer 43. The first mask pattern 45 may include an opening positioned in the first cell region CR1. Subsequently, the insulating layer 44, the etch stop layer 43, and the first stack ST1 may be etched using the first mask pattern 45 as an etch barrier to form a first sub-channel hole SCH1. The first sub-channel hole SCH1 may be positioned in the first cell region CR1.

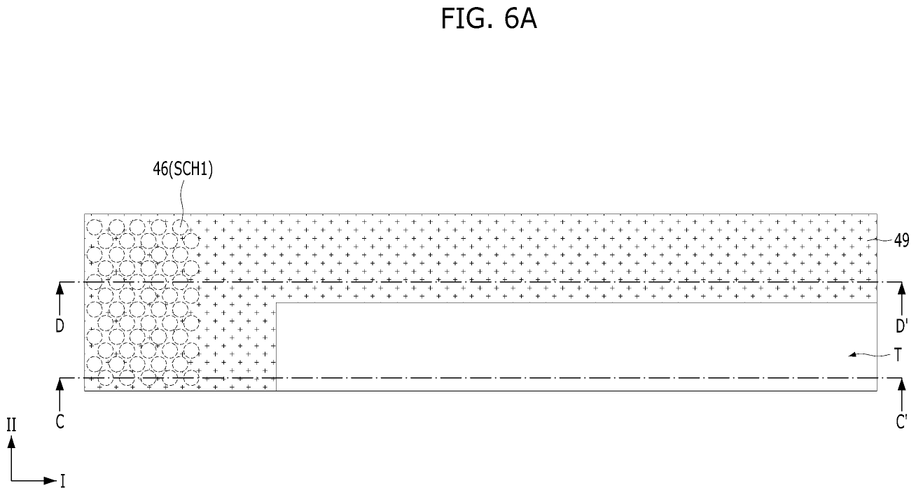

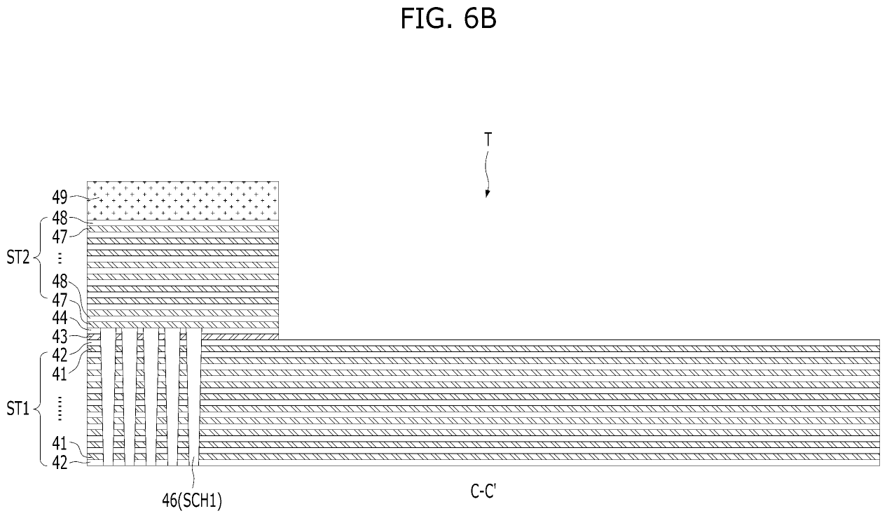

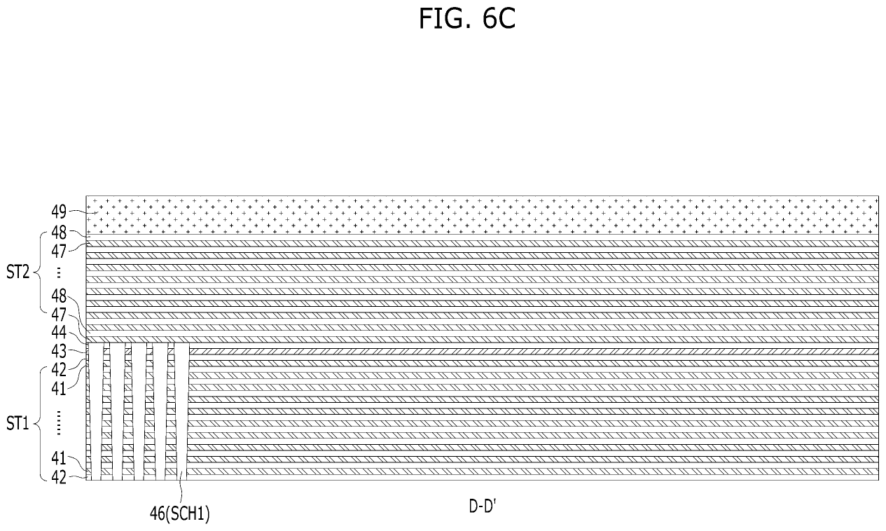

Referring to FIGS. 6A to 6C, a sacrificial layer 46 may be formed in the first sub-channel hole SCH1. The sacrificial layer 46 may include a material having a great etch selectivity with respect to the first material layer 41 and the first insulating layer 42.

Subsequently, a second stack ST2 including the second cell region CR2 and the second contact region CTR2 may be formed on the etch stop layer 43 and the insulating layer 44. The second stack ST2 may include second material layers 47. In an embodiment, the second stack ST2 may include the second material layers 47 and second insulating layers 48 that are alternately stacked. The second material layers 47 may be for forming a gate line such as a select lines and a word line. The second material layers 47 may include a sacrificial material such as nitride or may include a conductive material such as polysilicon or tungsten. The second insulating layer 48 may insulate stacked gate lines from each other. The second insulating layer 48 may include an insulating material such as oxide, nitride, an air gap, or a void.

Subsequently, a second mask pattern 49 may be formed on the second stack ST2. The second mask pattern 49 may be formed to partially expose the first contact region CTR1. The second mask pattern 49 may have a shape covering the second cell region CR2 and partially exposing the second contact region CTR2. The second mask pattern 49 may expose a region of the first contact region CTR1 where the first step structure is to be formed and may cover a region of the second contact region CTR2 where the second step structure is to be formed. The second mask pattern 49 may include photoresist.

Subsequently, the second stack ST2 may be etched using the second mask pattern 49 as an etch barrier. At this time, the second stack ST2 may be etched to expose the etch stop layer 43. Because an etching depth is controlled using the etch stop layer 43, the first material layer 41 and the first insulating layer 42 may be alternately etched using the same etching recipe. Because the second stack ST2 is etched without changing the etching recipe, occurrence of an inclination of etch surfaces of the first material layer 41 and the second insulating layer 42 may be improved.

Subsequently, the exposed etch stop layer 43 may be etched. In an embodiment, the etch stop layer 43 may be etched using the second mask pattern 49 as an etch barrier. In an embodiment, after removing the second mask pattern 49, the etch stop layer 43 may be etched by a wet etching method using phosphoric acid or the like. Through this, a trench T extending through the second stack ST2 and the etch stop layer 43 and partially exposing the first contact region CTR1 may be formed. A sidewall of the trench T may have a vertical profile and may expose a region of the first contact region CTR1 where the first step structure is to be formed.

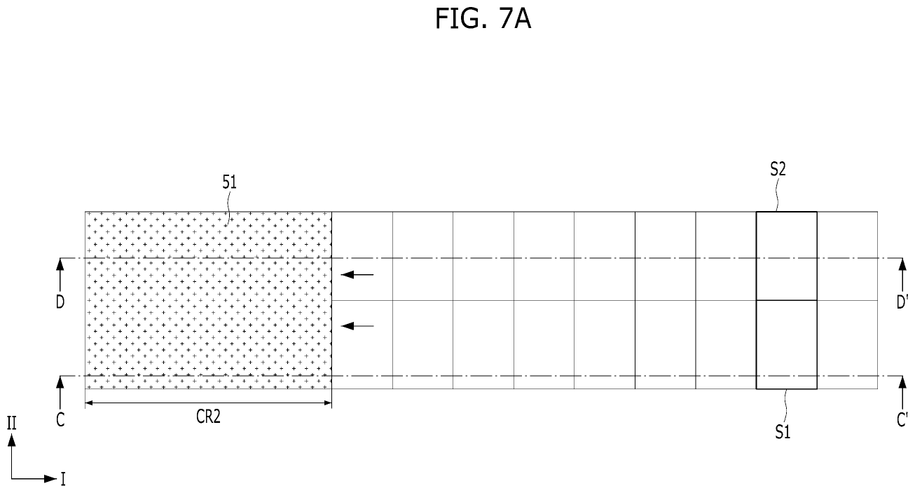

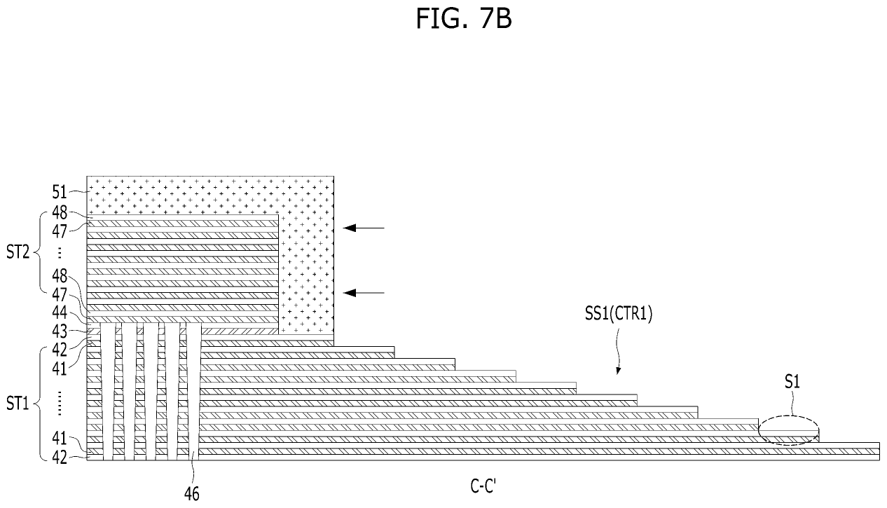

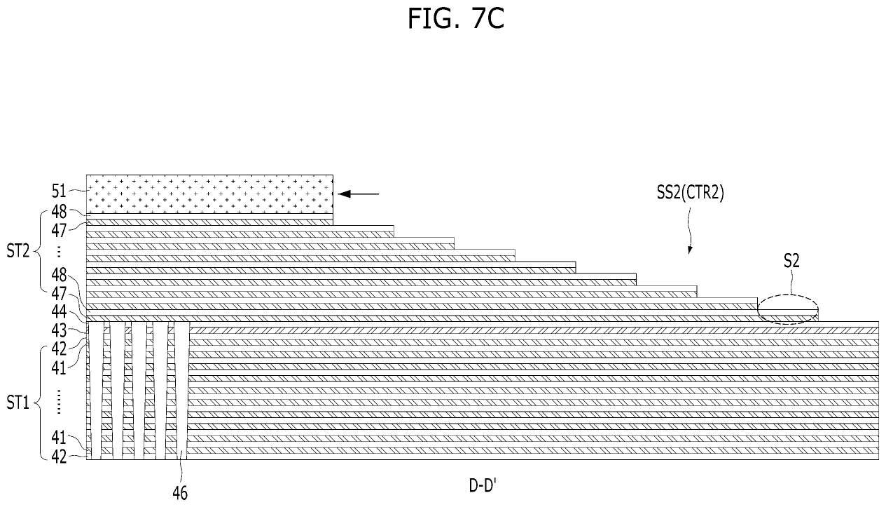

Referring to FIGS. 7A to 7C, the first step structure SS1 and the second step structure SS2 may be formed. The first step structure SS1 positioned in the first stack ST1 and the second step structure SS2 positioned in the second stack ST2 may be formed, by patterning the first and second contact regions CTR1 and CTR2, respectively, in a step shape.

Each of the first material layers 41 may be exposed by the first step structure SS1. Each of the second material layers 42 and the etch stop layer 43 may be exposed by the second step structure SS2. The first and second step structures SS1, and SS2 may extend in the first direction I and may be adjacent to each other in the second direction II. The first and second step structures SS1, and SS2 may be in contact to each other. The first steps S1 included in the first step structure SS1 and the second steps S2 included in the second step structure SS2 may be aligned in the second direction II.

The first step structure SS1 and the second step structure SS2 may be formed using the same mask pattern. In an embodiment, a third mask pattern 51 may be formed on the second stack ST2. The third mask pattern 51 may cover the second cell region CR2 and expose a portion of the second contact region CTR2 and a portion of the first contact region CTR1. Subsequently, the first contact region CTR1 and the second contact region CTR2 may be etched using the third mask pattern 51 as an etch barrier. Subsequently, the third mask pattern 51 may be reduced in the first direction I, and the first contact region CTR1 and the second contact region CTR2 may be etched using the reduced third mask pattern 51 as an etch barrier. The first contact region CTR1 and the second contact region CTR2 may be patterned in a step shape extending in the first direction I, by repeatedly performing reduction of the third mask pattern 51 and an etching process. Through this, the first step structure SS1 and the second step structure SS2 having the same shape may be formed in the first contact region CTR1 and the second contact region CTR2, respectively.

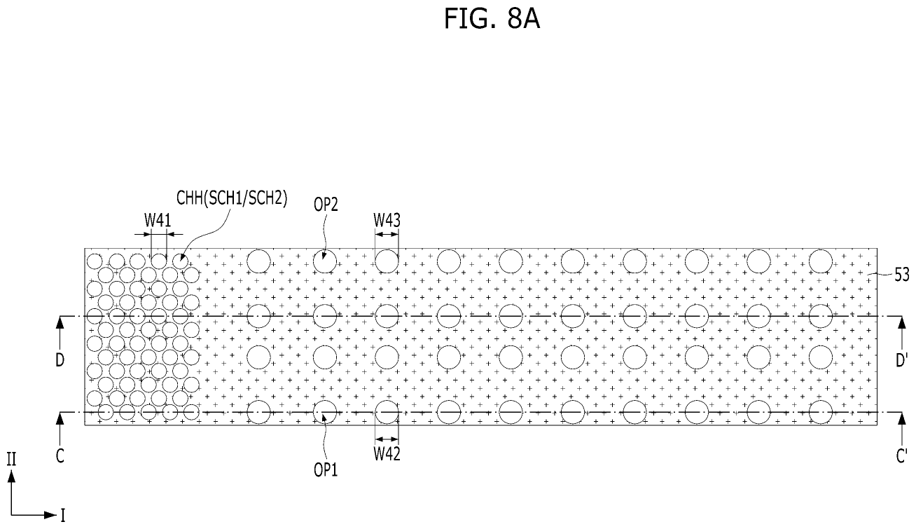

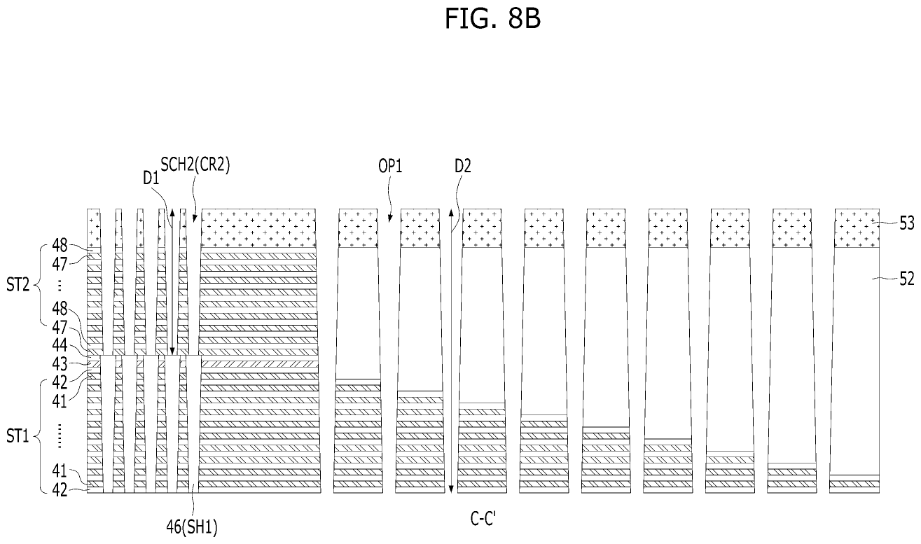

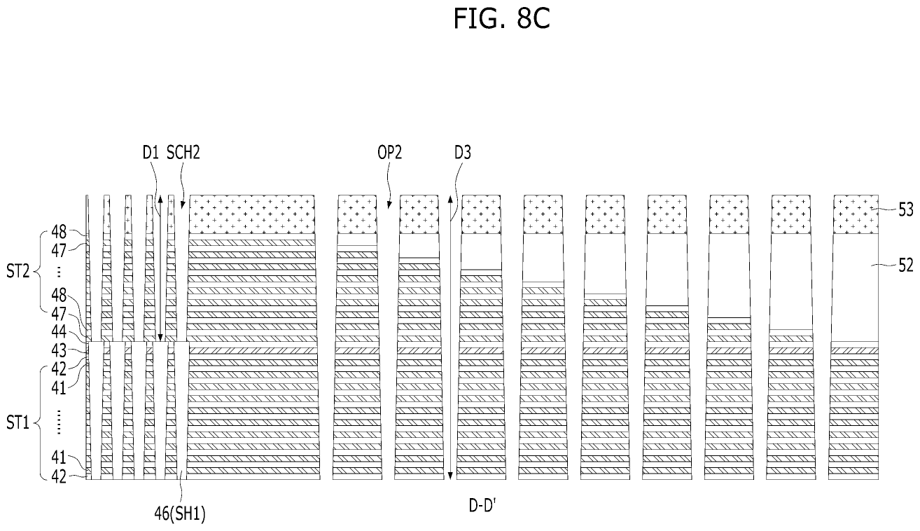

Referring to FIGS. 8A to 8C, an insulating layer 52 may be formed on the second stack. The insulating layer 52 may cover the first step structure SS1 and the second step structure SS2. Subsequently, a fourth mask pattern 53 may be formed on the second stack ST2 and the insulating layer 52. Subsequently, the insulating layer 52 and the second stack ST2 may be etched using the fourth mask pattern 53 as an etch barrier to form second sub-channel holes SCH2 connected to corresponding first sub-channel holes SCH1.

The second sub-channel holes SCH2 may be positioned in the second cell region CR2 of the second stack ST2. The second sub-channel holes SCH2 may extend through the second stack ST2 and expose the sacrificial layer 46. The second sub-channel holes SCH2 may have a first depth D1 and a first width W41. Through this, channel holes CHH, each including a first sub-channel hole SCH1 and a corresponding second sub-channel hole SCH2 may be formed. A bottom width of the first sub-channel hole SCH1 and a top width of the second sub-channel hole SCH2 may be different from each other, thus, a sidewall of the channel hole CHH may include a step difference S due to a width difference. The step difference S may be positioned between the first stack ST1 and the second stack ST2.

The insulating layer 52 and the second stack ST2 may be etched using the fourth mask pattern 53 as an etch barrier to form a first opening OP1 extending through the first step structure SS1. The first opening OP1 may pass through the insulating layer 52 and extend into the first step structure SS1. The first opening OP1 may have a second depth D2 and a second width W42. The second depth D2 may be greater than the first depth D1, and the second width W42 may be greater than the first width W41.

The second stack ST2 may be etched using the fourth mask pattern 53 as an etch barrier to form a second opening OP2 extending through the second step structure SS2. The second opening OP2 may pass through the insulating layer 52, the second step structure SS2, and the etch stop layer 43 and extend into the first stack ST1. The second opening OP2 may be adjacent to the first opening OP1 in the second direction II. The second opening OP2 may have a third depth D3 and a third width W43. The third depth D3 may be greater than the first depth D1, and the third width W43 may be greater than the first width W41. The second depth D2 and the third depth D3 may be substantially the same. The second width W42 and the third width S43 may be substantially the same.

The first opening OP1 may be formed when forming the second sub-channel hole SCH2 or may be formed in a separate process. The second opening OP2 may be formed when forming the second sub-channel hole SCH2 or may be formed in a separate process. In an embodiment, the second sub-channel hole SCH2, the first opening OP1, and the second opening OP2 may be formed using the fourth mask pattern 53. When forming the second sub-channel hole SCH2, the first and second openings OP1 and OP2 may be formed.

The first and second openings OP1 and OP2 may be formed to have a width greater than the width of the second sub-channel hole SCH2. In this case, an etching amount of the first and second openings OP1 and OP2 may be greater than an etching amount of the second sub-channel hole SCH2 by a loading effect. Therefore, the first and second openings OP1 and OP2 may be formed in a depth greater than that of the second sub-channel hole SCH2. The first and second openings OP1 and OP2 may be formed in a single etching process and may not include a step difference on the sidewall.

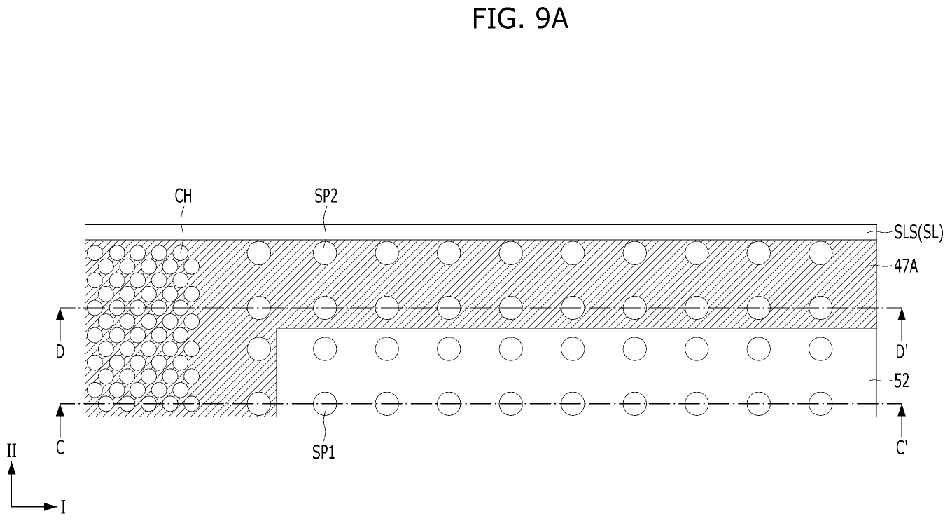

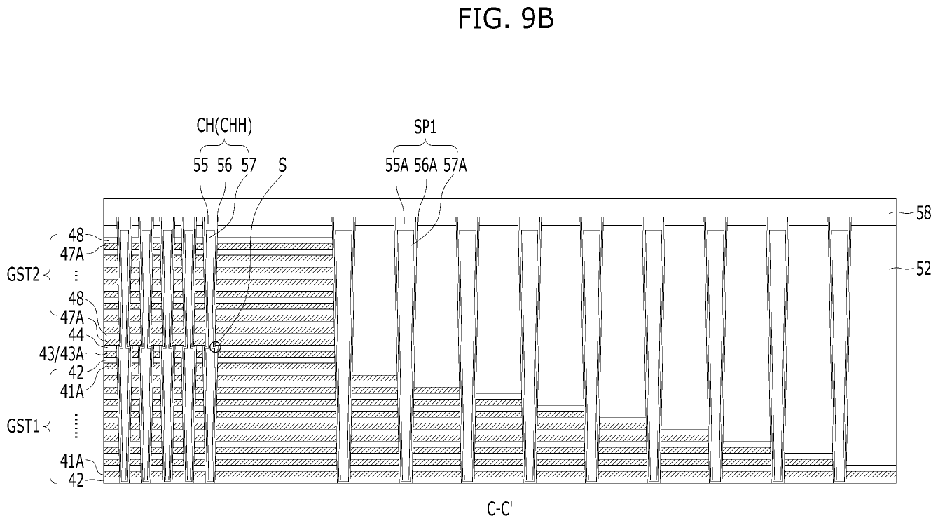

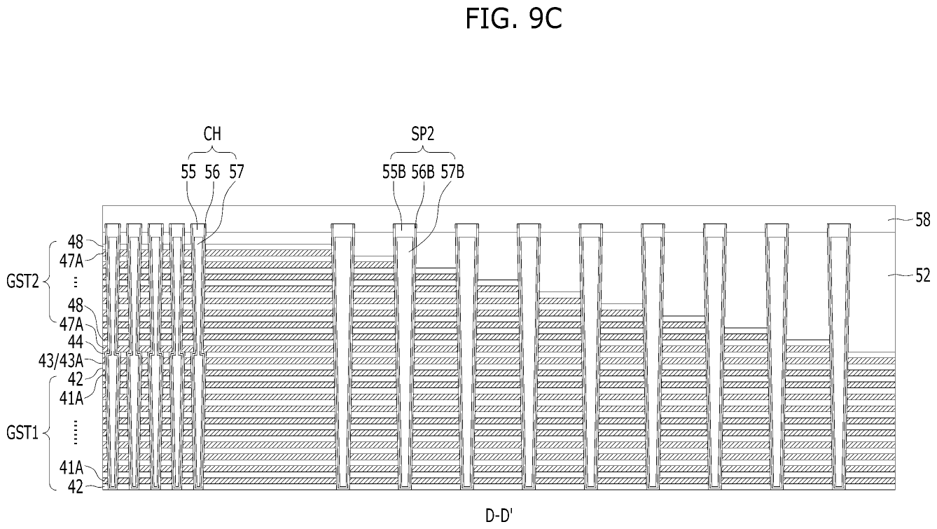

Referring to FIGS. 9A to 9C, the first sub-channel hole SCH1 may be reopened by removing the sacrificial layer 46. Subsequently, the channel structure CH may be formed in the channel hole CHH. According to the illustrated embodiment, the channel structure CH may include a channel layer 55, a memory layer 56, and an insulating core 57. However, in other embodiments, (not shown), the channel structure CH may include at least one of a channel layer 55, a memory layer 56, and an insulating core 57. A sidewall of the channel structure CH may include a step difference S transferred from the channel hole CHH.

The first support SP1 may be formed in the first opening OP1. In the illustrated embodiment, the first support SP1 may include a first dummy channel layer 55A, a first dummy memory layer 56A, and a first dummy insulating core 57A. However, in other embodiments, (not shown), the first support SP1 may include at least one of a first dummy channel layer 55A, a first dummy memory layer 56A, and a first dummy insulating core 57A. A sidewall of the first support SP1 may have a shape transferred from the first opening OP1. The sidewall of the first support SP1 may not include a step change in its width and may be referred to as a non-stepped sidewall. The first support SP1 may have a width greater than that of the channel structure CH.

The second support SP2 may be included in the second opening OP2. The second support SP2 may include at least one of a second dummy channel layer 55B, a second dummy memory layer 56B, and a second dummy insulating core 57B. A sidewall of the second support SP2 may have a shape transferred from the second opening OP2. The sidewall of the second support SP2 may not have a step change in its width, and may be referred to as a non-stepped sidewall. The second support SP2 may have a width greater than that of the channel structure CH.

The first support SP1 may be formed when forming the channel structure CH or may be formed in a separate process. The second support SP2 may be formed when forming the channel structure CH or may be formed in a separate process. In an embodiment, when forming the channel structure CH, the first support SP1 and the second support SP2 may be formed. At least one of the first and second supports SP1 and SP2 may include a dummy channel layer.

Subsequently, an insulating layer 58 may be formed to cover the channel structures CH, the first supports SP1, and the second supports SP2. Subsequently, the first material layers 41 and the second material layers 47 may be replaced with conductive layers. In an embodiment, a slit SL extending through the insulating layers 58 and 52, the second stack ST2, the etch stop layer 43, and the first stack ST1 may be formed. Subsequently, the first material layers 41 and the second material layers 47 may be replaced with conductive layers through the slit SL. Openings may be formed by selectively etching the first material layers 41 and the second material layers 47 through the slit SL, and conductive layers may be formed in the openings.

Through this, the first gate structure GST1 including first gate lines 41A and the first insulating layers 42 that are alternately stacked may be formed. The second gate structure GST2 including second gate lines 47A and the second insulating layers 48 that are alternately stacked may be formed. When replacing the first material layers 41 and the second material layers 47 with the conductive layers, the etch stop layer 43 may remain or may be replaced with a gate line 43A. The gate line 43A may be included in the first gate structure GST1.

In a variation of the described embodiment, when the first material layers 41 and the second material layers 47 include a conductive material, the above-mentioned replacement process may be omitted. In this case, the first stack ST1 may be the first gate structure GST1, the second stack GST2 may be the second gate structure GST2, and the etch stop layer 43 may remain.

At least one of the first material layers 41, the second material layers 47, and the etch stop layer 43 may be replaced with a conductive layer. When replacing the first material layers 41 and the second material layers 47 with conductive layers, the etch stop layer 43 may remain or may be replaced with the gate line 43A. The gate line 43A may be included in the first gate structure GST1. In an embodiment, openings may be formed by selectively etching the first material layers 41, the second material layers 47, and the etch stop layer 43, and conductive layers may be formed in the openings. When the first material layers 41, the second material layers 47, and the etch stop layer 43 include nitride, the first material layers 41, the second material layers 47, and the etch stop layer 43 may be selectively etched in a dip-out process using phosphoric acid. In an embodiment, when the etch stop layer 43 includes polysilicon, the etch stop layer 43 may be selectively etched using nitric acid or a dry cleaning process.

Subsequently, a slit structure SLS may be formed in the slit SL. The slit structure SLS may include at least one of an insulating material, a conductive material, and a semiconductor material. In an embodiment, the slit structure SLS may include a source contact plug and an insulating spacer surrounding a sidewall of the source contact plug.

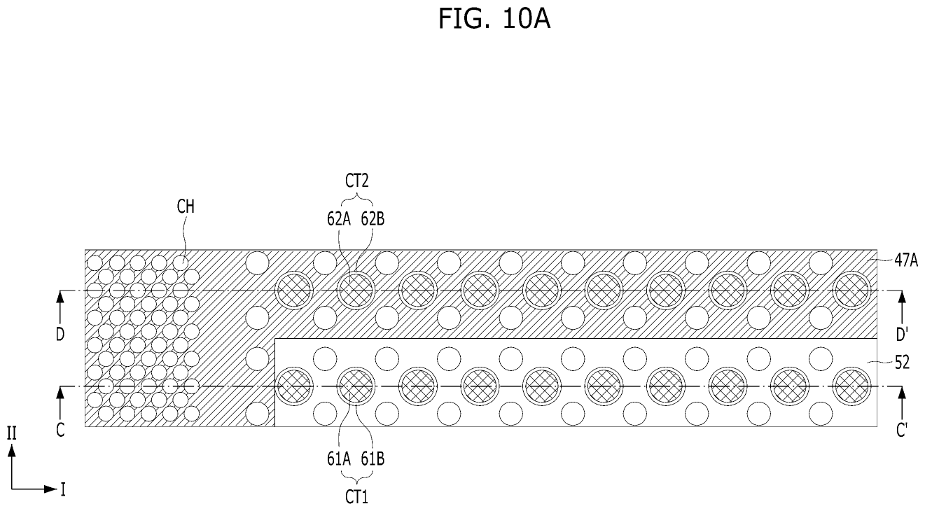

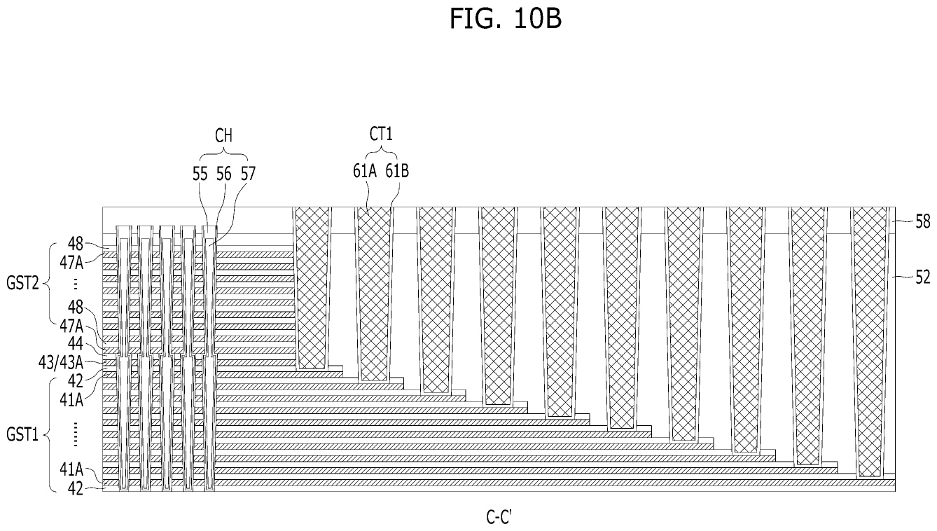

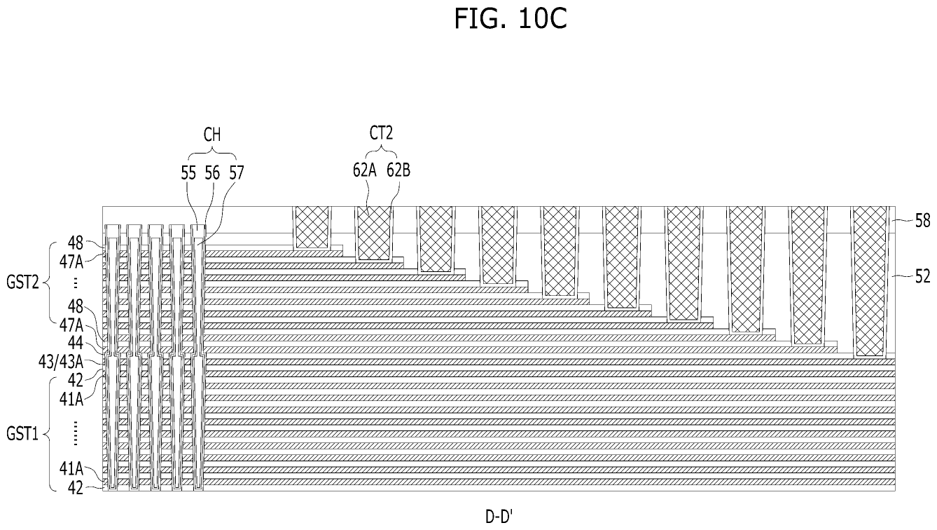

Referring to FIGS. 10A to 10C, the first and second contact plugs CT1 and CT2 may be formed. The first contact plug CT1 may be positioned between the first supports SP1. The first contact plug CT1 may be positioned centrally between adjacent first supports SP1. In the illustrated embodiment, one first contact plug CT1 may be positioned centrally between four adjacent first supports SP1. Forming the first contact plugs CT1 may include first forming openings exposing each of the first gate lines 41A through the insulating layers 52 and 58, then a first barrier layer 61B may be formed in the openings, and following the formation of the first barrier layer 61B, a first metal layer 61A may be formed to fill the remaining gap formed by first barrier layer 61B. The first contact plugs CT1 may extend through the insulating layers 52 and 58 and may be electrically connect to a corresponding one of the first gate lines 41A.

The second contact plugs CT2 may be positioned between the second supports SP2. The second contact plugs CT2 may be positioned centrally between the second supports SP2. In the illustrated embodiment, one second contact plug CT1 may be positioned centrally between four adjacent second supports SP2. Forming the second contact plugs CT1 may include first forming openings exposing each of the second gate lines 47A through the insulating layers 52 and 58, then a second barrier layer 62B may be formed in the openings, and a second metal layer 62A may be formed following the formation of the second barrier layer 62B to fill the remaining gap formed by the second barrier layer 62B. The second contact plug CT2 may extend through the insulating layers 52 and 58 and may be electrically connected to the second gate line 47A. The first and second metal layers 61A and 62A may include a metal such as tungsten or molybdenum. The first and second barrier layers 61B and 62B may include metal nitride such as tungsten nitride, molybdenum nitride, titanium nitride, or tantalum nitride.

According to the manufacturing method as described above, after exposing the first contact region CTR1 by forming the trench T, the first contact region CTR1 and the second contact region CTR2 may be patterned in a step shape. Therefore, when forming the second step structure SS2 in the second contact region CTR2, the first step structure SS1 may be formed in the first contact region CTR1. A process cost may be reduced by simultaneously patterning the first stack ST1 and the second stack ST2 to simultaneously form the first step structure SS1 and the second step structure SS2 positioned at different levels.

Because the trench T is formed using the etch stop layer 43, the second material layers 47 and the second insulating layers 48 may be etched using the same recipe. Therefore, compared to a case where the second material layers 47 and the second insulating layers 48 are alternately etched while changing a recipe, the trench T may have a vertical profile, and an increase in an area of a step structure due to an inclination of the trench T may be improved.

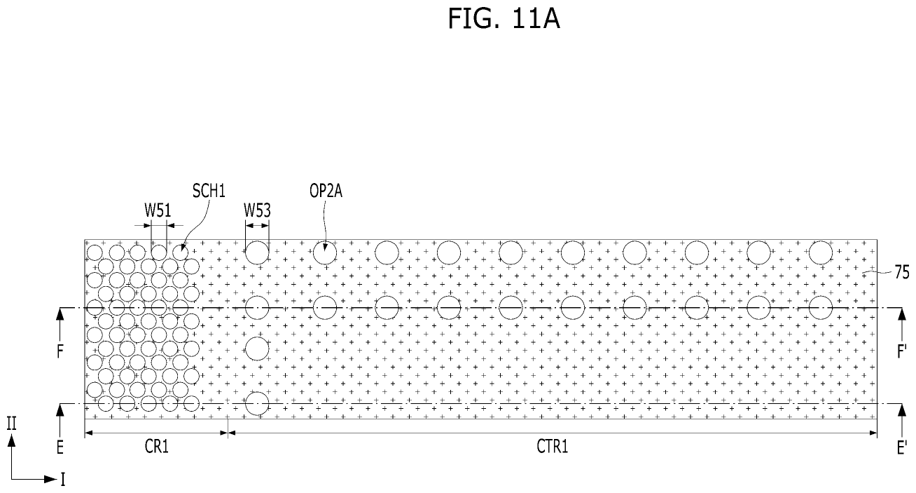

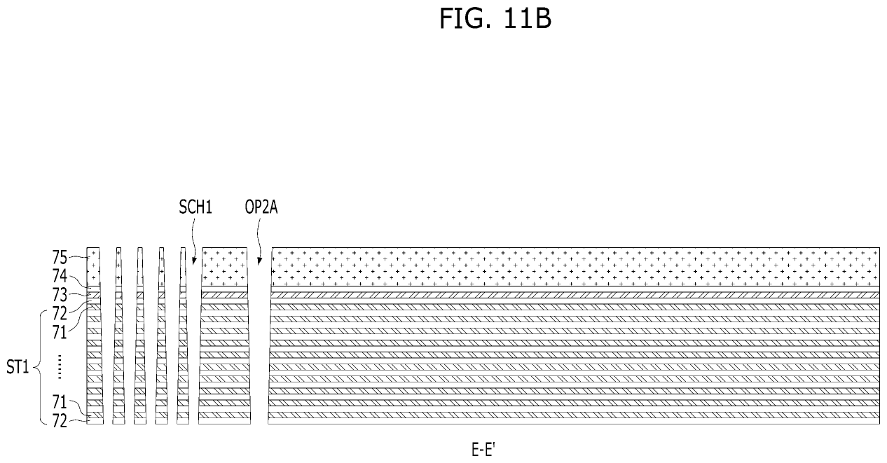

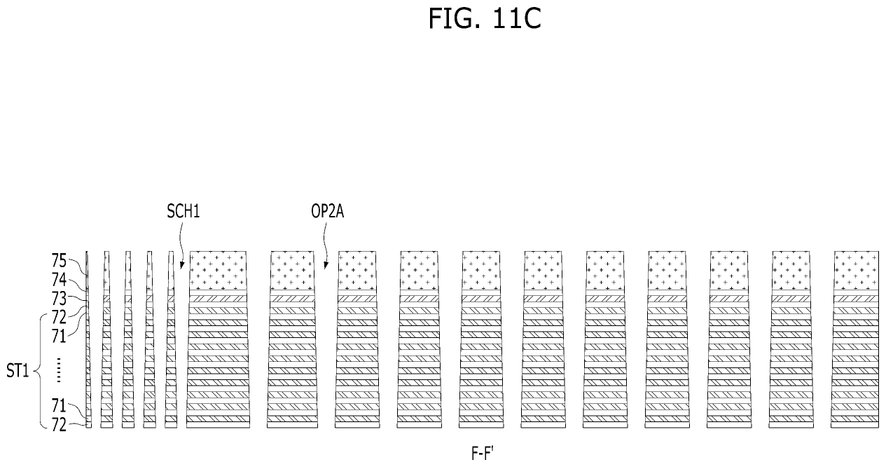

FIGS. 11A to 16A, 11B to 16B, and 11C to 16C are diagrams illustrating a method of manufacturing a semiconductor device according to an embodiment of the present disclosure. FIG. A of each FIG. is a plan view, FIG. B of each number is an E-E′ cross-sectional view of FIG. A, and FIG. C of each number is an F-F′ cross-sectional view of FIG. A. Hereinafter, content overlapping the above-described content is omitted.

Referring to FIGS. 1A and 11B, the first stack ST1 including the first cell region CR1 and the first contact region CTR1 may be formed. The first stack ST1 may include first material layers 71 and first insulating layers 72 that are alternately stacked. Subsequently, an etch stop layer 73 and an insulating layer 74 may be formed on the first stack ST1.

Subsequently, a first mask pattern 75 may be formed on the etch stop layer 73. Subsequently, the etch stop layer 73 and the first stack ST1 may be etched using the first mask pattern 75 as an etch barrier to form the first sub-channel hole SCH1 and a first sub-opening OP2A. The first sub-channel hole SCH1 may be positioned in the first cell region CR1, and the first sub-opening OP2A may be positioned in the first contact region CTR1. The first contact region CTR1 may include a region where the first step structure is to be formed and a remaining region, and the first sub-opening OP2A may be positioned in the remaining region.

The first sub-channel hole SCH1 and the first sub-opening OP2A may have substantially the same width or may have different widths. The first sub-channel hole SCH1 may have a first width W51, and the first sub-opening OP2A may have a third width W53 greater than the first width W51.

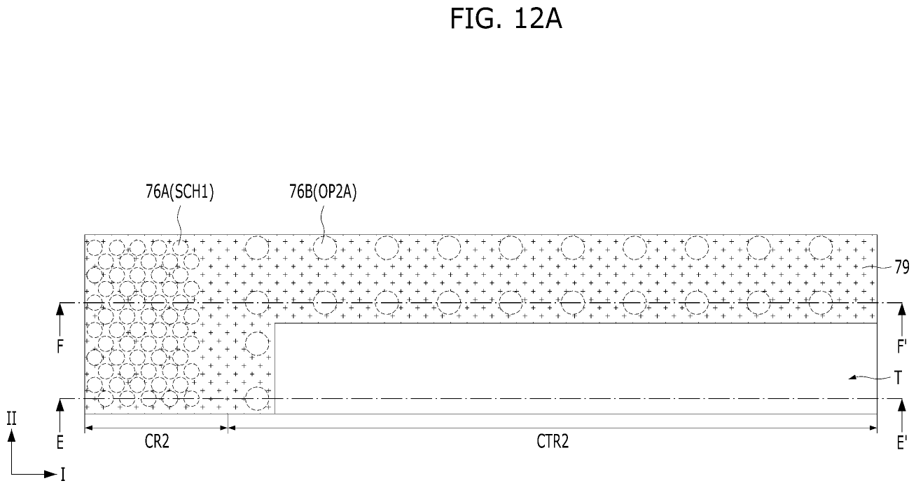

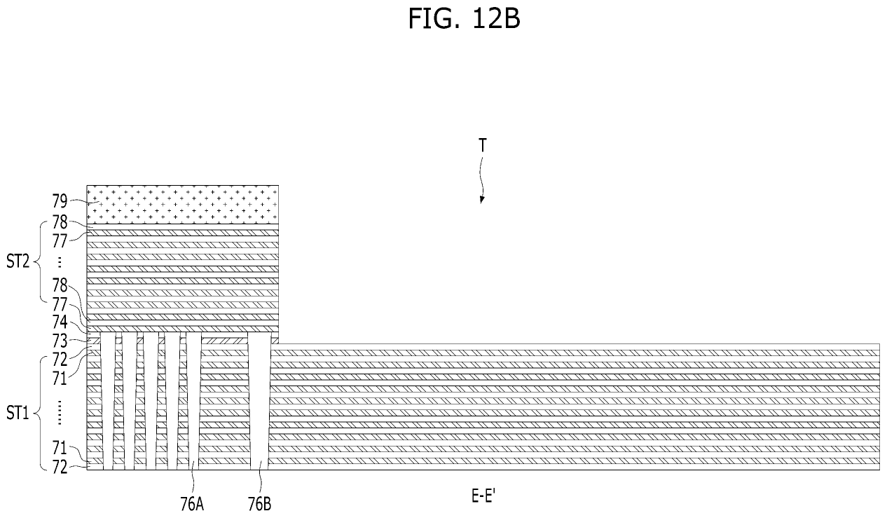

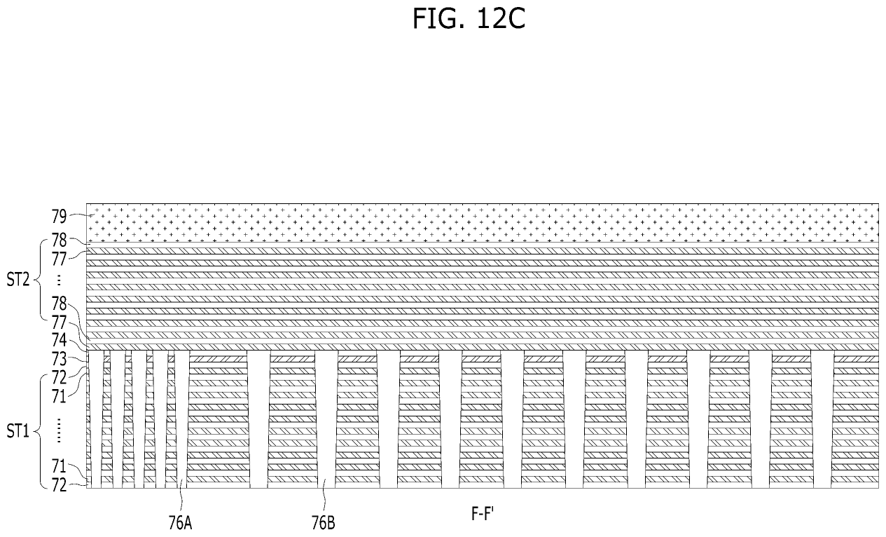

Referring to FIGS. 12A to 12C, a first sacrificial layer 76A may be formed in the first sub-channel hole SCH1. A second sacrificial layer 76B may be formed in the first sub-opening OP2A. When forming the first sacrificial layer 76A, the second sacrificial layer 76B may be formed. The first sacrificial layer 76A and the second sacrificial layer 76B may include a material having a great etch selectivity with respect to the first material layer 71 and the first insulating layer 72.

Subsequently, the second stack ST2 including the second cell region CR2 and the second contact region CTR2 may be formed on the etch stop layer 73. The second stack ST2 may include second material layers 77 and second insulating layers 78 that are alternately stacked.

Subsequently, a second mask pattern 79 may be formed on the second stack ST2. The second mask pattern 79 may cover the second cell region CR2 and partially expose the second contact region CTR2. The second mask pattern 79 may expose a region of the first contact region CTR1 where the first step structure is to be formed and may cover a region of the second contact region CTR2 where the second step structure is to be formed.

Subsequently, the second stack ST2 is etched using the second mask pattern 79 as an etch barrier to expose the etch stop layer 73, and the exposed etch stop layer 73 may be etched. Through this, the trench T extending through the second stack ST2 and the etch stop layer 73 and exposing a region of the first contact region CTR1 where the first step structure is to be formed may be formed.

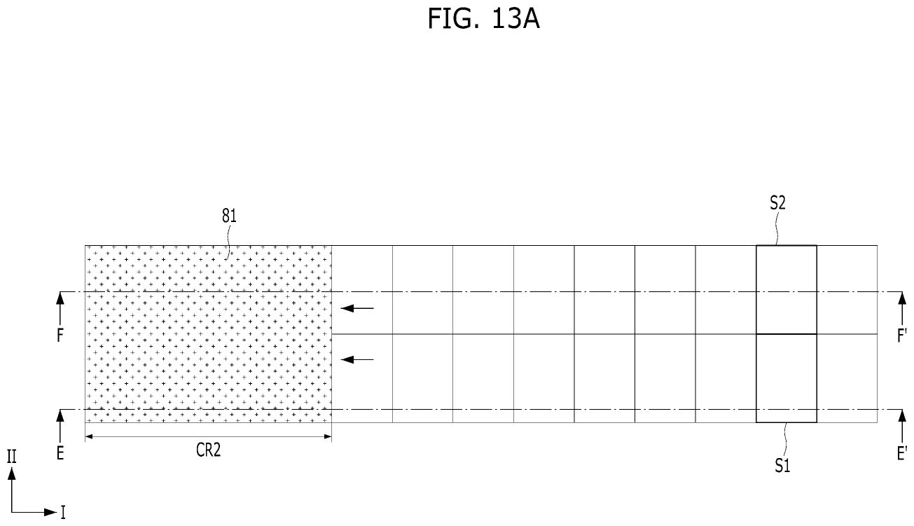

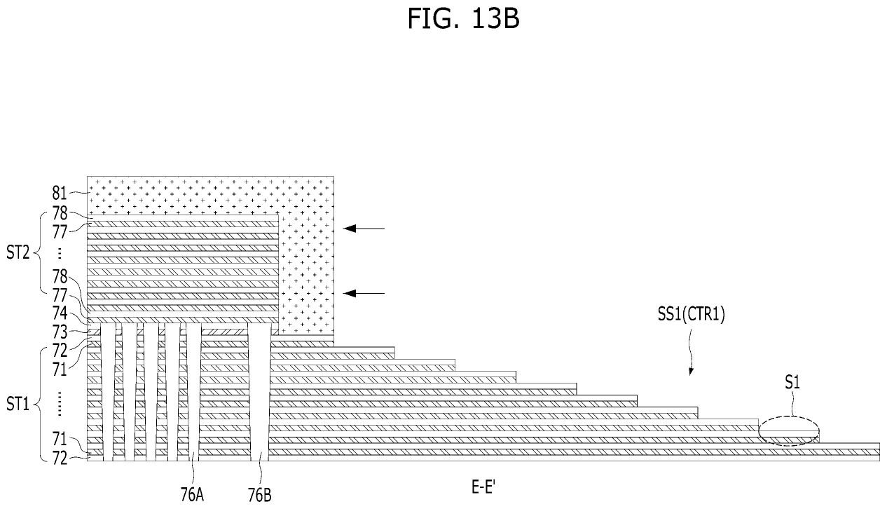

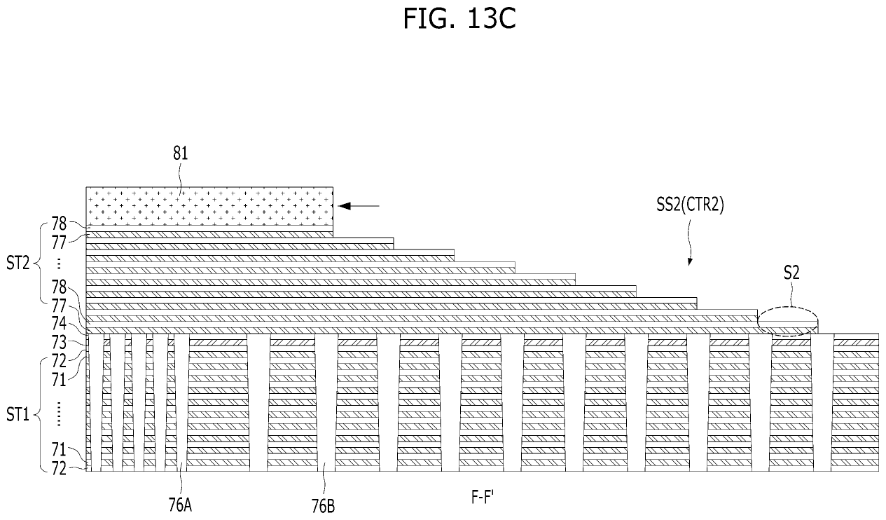

Referring to FIGS. 13A to 13C, a third mask pattern 81 may be formed on the second stack ST2. The first step structure SS1 and the second step structure SS2 may be formed by repeatedly performing reduction of the third mask pattern 81 and an etching process. Because the first sub-opening OP2A and the second sacrificial layer 76B are not formed in the region where the first step structure SS1 is to be formed, the first material layers 71 and the insulating layers 72 may be etched to form the first step structure SS1. The second step structure SS2 may be formed on the first sub-opening OP2A and the second sacrificial layer 76B. The first step structure SS1 and the second step structure SS2 may extend in the first direction I and may be adjacent to each other in the second direction II. The first step structure SS1 and the second step structure SS2 may be in contact to each other. The first steps S1 included in the first step structure SS1 and the second steps S2 included in the second step structure SS2 may be aligned in the second direction II.

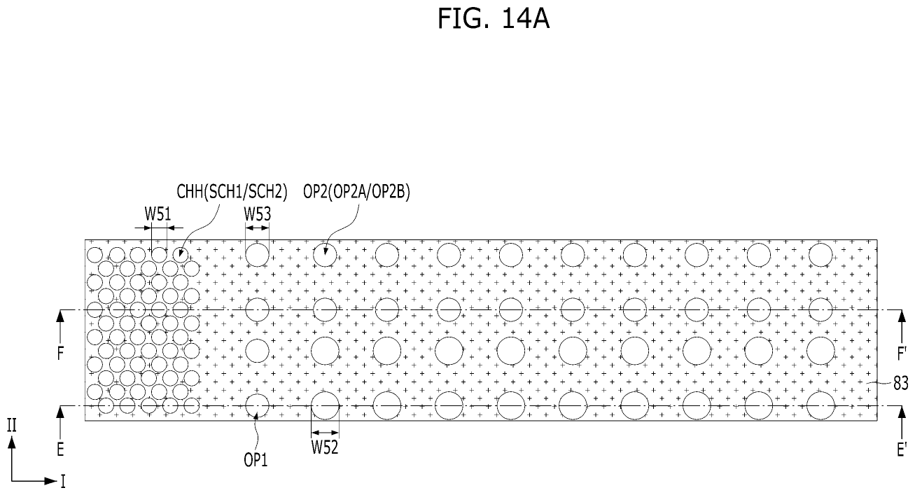

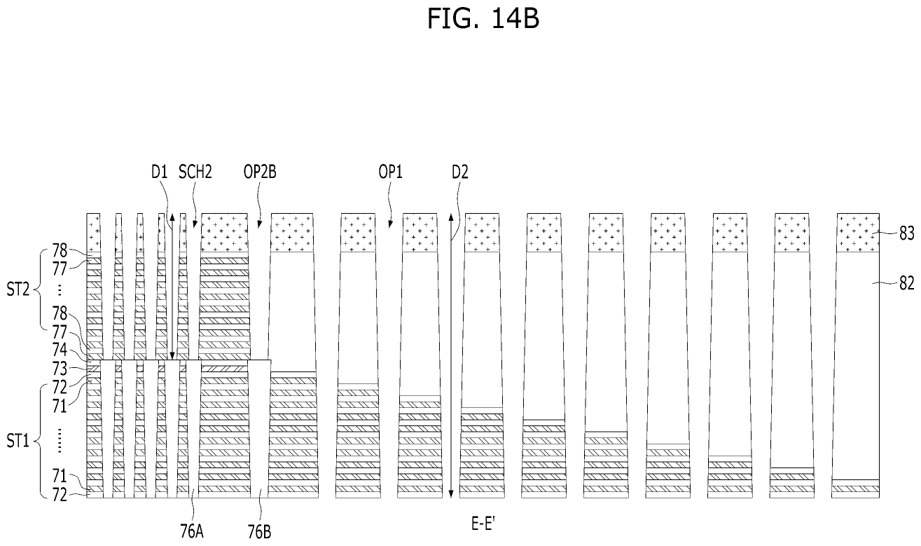

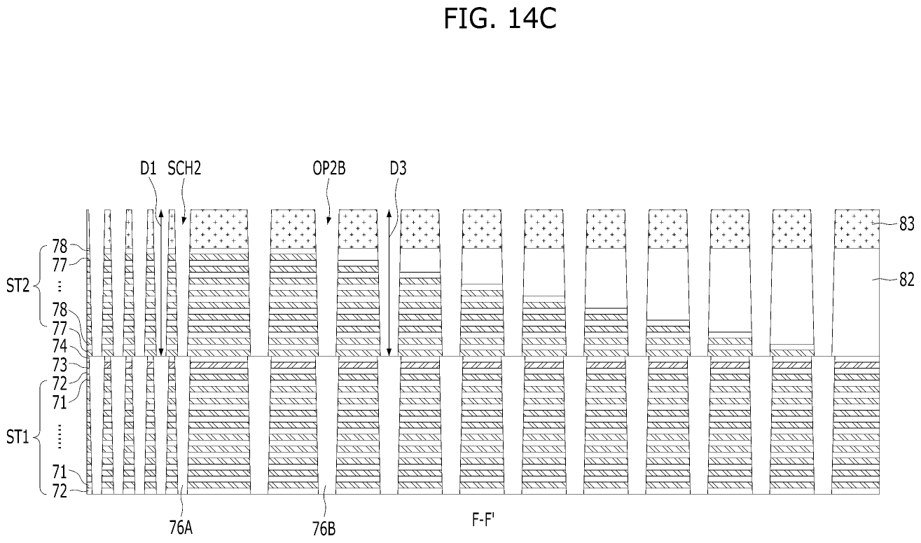

Referring to FIGS. 14A to 14C, a fourth mask pattern 83 may be formed on the second stack ST2. The insulating layer 82 and the second stack ST2 may be etched using the fourth mask pattern 83 as an etch barrier to form the second sub-channel hole SCH2 connected to the first sub-channel hole SCH1. The second sub-channel holes SCH2 may be positioned in the second cell region CR2 of the second stack ST2. The second sub-channel hole SCH2 may have the first depth D1 and a first width W51. Through this, the channel hole CHH including the first sub-channel hole SCH1 and the second sub-channel hole SCH2 may be formed.

The insulating layer 82 and the second stack ST2 may be etched using the fourth mask pattern 83 as an etch barrier to form the second sub-opening OP2B. The second sub-opening OP2B may extend through the second step structure SS2 and may be connected to the first sub-opening OP2A. The second sacrificial layer 76B may be exposed through the second sub-opening OP2B. The second opening OP2 may have the third depth D3 and a third width W53. The third depth D3 may be substantially the same as the first depth D1, and the third width W53 may be greater than the first width W51. Through this, the second opening OP2 including the first sub-opening OP2A1 and the second sub-opening OP2B may be formed.

The insulating layer 82 and the second stack ST2 may be etched using the fourth mask pattern 83 as an etch barrier to form the first opening OP1 extending through the first step structure SS1. The first opening OP1 may pass through the insulating layer 82 and extend into the first step structure SS1. The first opening OP1 may have the second depth D2 and a second width W52. The second depth D2 may be greater than the first depth D1 and the third depth D3, and the second width W52 may be greater than the first width W51 and the second width W52.

The second sub-channel hole SCH2, the first opening OP1, and the second sub-opening OP2B may be formed using the fourth mask pattern 83 as an etch barrier. When forming the second sub-opening OP2B and the second sub-channel hole SCH2, the first opening OP1 may be formed. The first opening OP1 may be formed to have a width greater than that of the second sub-channel hole SCH2 and the second sub-opening OP2B, and an etching amount of the first opening OP1 may be greater than an etching amount of the second sub-channel hole SCH2 and the second sub-opening OP2B by a loading effect. Therefore, the first opening OP1 may be formed in a depth greater than that of the second sub-channel hole SCH2 and the second sub-opening OP2B. Therefore, the first opening OP1 may be formed in a single etching process and may not include a step difference on a sidewall.

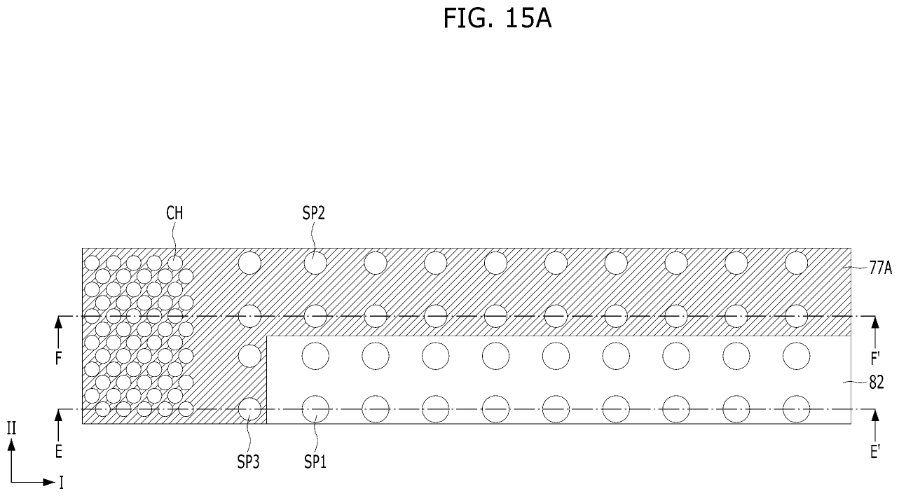

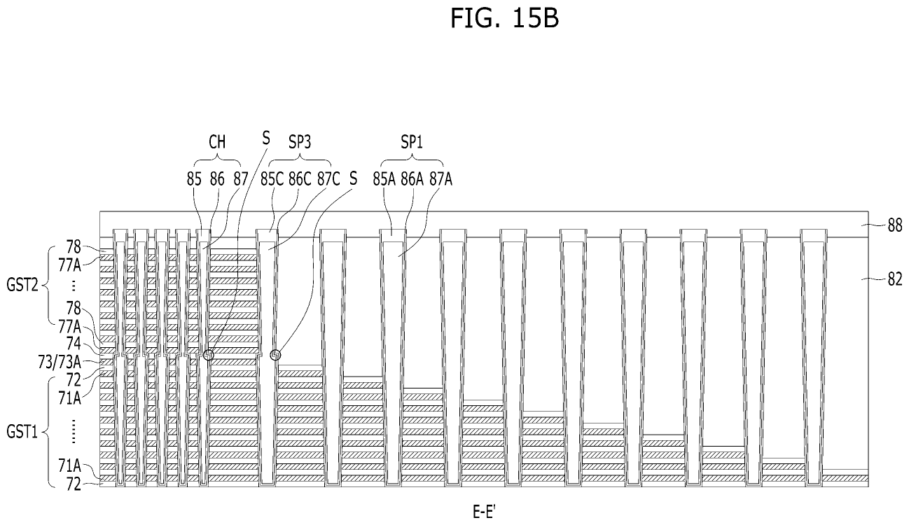

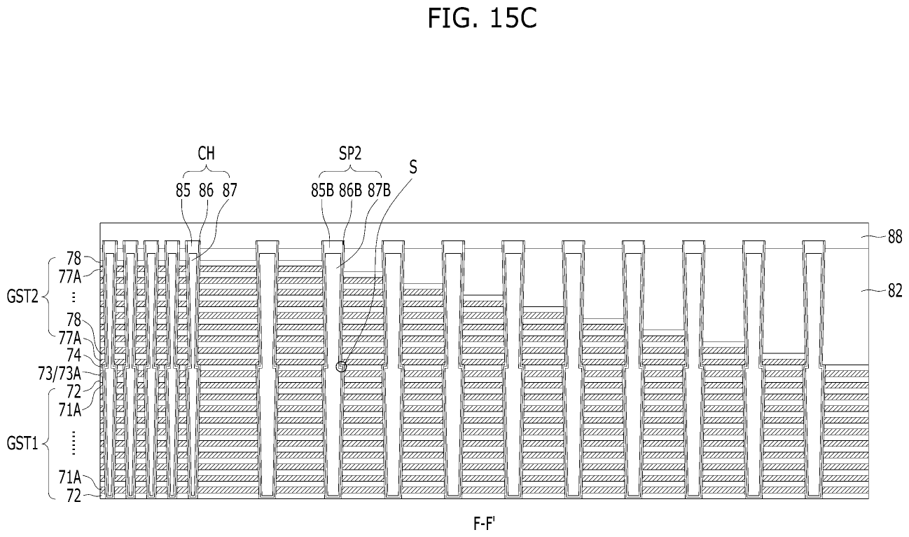

Referring to FIGS. 15A to 15C, the first sub-channel hole SCH1 may be reopened by removing the first sacrificial layer 76A. Subsequently, the channel structure CH may be formed in the channel hole CHH. In the illustrated embodiment, the channel structure CH may include a channel layer 85, a memory layer 86, and an insulating core 87. However, in other embodiments, the channel structure CH may include at least one of a channel layer 85, a memory layer 86, and an insulating core 87. A sidewall of the channel structure CH may include a step difference S transferred from the channel hole CHH.

The first support SP1 may be formed in the first opening OP1. The first support SP1 may include a first dummy channel layer 85A, a first dummy memory layer 86A, and a first dummy insulating core 87A. In some embodiments, (not shown) the first support SP1 may include at least one of a first dummy channel layer 85A, a first dummy memory layer 86A, and a first dummy insulating core 87A. A sidewall of the first support SP1 may have a shape transferred from the first opening OP1 and may include a non-stepped sidewall. The first support SP1 may have a width greater than the width of the channel structure CH.

The first sub-opening OP2A may be reopened by removing the second sacrificial layer 76B. When the first sacrificial layer 76A is removed, the second sacrificial layer 76B may be removed. Subsequently, the second support SP2 may be formed in the second opening OP2. The second support SP2 may be adjacent to the first support SP1 in the second direction II. The second support SP2 may include a second dummy channel layer 85B, a second dummy memory layer 86B, and a second dummy insulating core 87B. In some embodiments, the second support SP2 may include at least one of a second dummy channel layer 85B, a second dummy memory layer 86B, and a second dummy insulating core 87B. A sidewall of the second support SP2 may have a shape transferred from the second opening OP2 and may include a step difference S on a sidewall. The second support SP2 may have a width greater than that of the channel structure CH and may have a width less than that of the first support SP1.

The third support SP3 may be formed in the second opening OP2. The third support SP3 may be positioned between the channel structure CH and the first support SP1, and may be adjacent to the first support SP1 in the first direction I. The third support SP3 may include at least one of a third dummy channel layer 85C, a second dummy memory layer 86C, and a second dummy insulating core 87C. A sidewall of the third support SP3 may have a shape transferred from the second opening OP2 and may include a step difference S on a sidewall. The third support SP3 may have a width greater than that of the channel structure CH and may have a width less than that of the first support SP1.

The first support SP1, the second support SP2, and the third support SP3 may be formed when forming the channel structure CH or may be formed in a separate process. In an embodiment, when forming the channel structure CH, the first support SP1, the second support SP2, and the third support SP3 may be formed. At least one of the first support SP1, the second support SP2, and the third support SP3 may include a dummy channel layer.

Subsequently, an insulating layer 88 may be formed to cover the channel structure CH, the first support SP1, the second support SP2, and the third support SP3. Subsequently, the first material layers 71 and the second material layers 77 may be replaced with conductive layers. Through this, the first gate structure GST1 including first gate lines 71A and first insulating layers 72 that are alternately stacked may be formed. The second gate structure GST2 including second gate lines 77A and second insulating layers 78 that are alternately stacked may be formed. When replacing the first material layers 71 and the second material layers 77 with conductive layers, the etch stop layer 73 may remain or may be replaced with a gate line 73A. The gate line 73A may be included in the first gate structure GST1. For reference, when the first material layers 71 and the second material layers 77 include a conductive material, a replacement process may be omitted. In this case, the first stack ST1 may be the first gate structure GST1, the second stack GST2 may be the second gate structure GST2, and the etch stop layer 73 may remain.

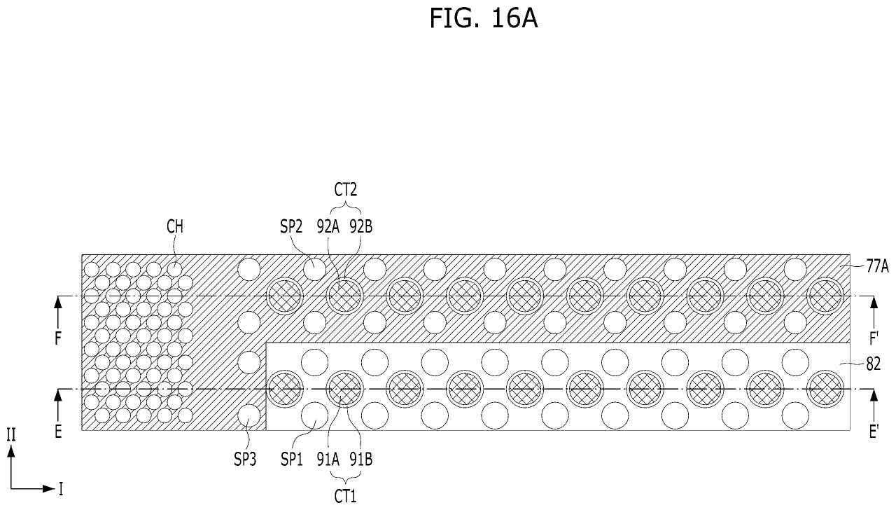

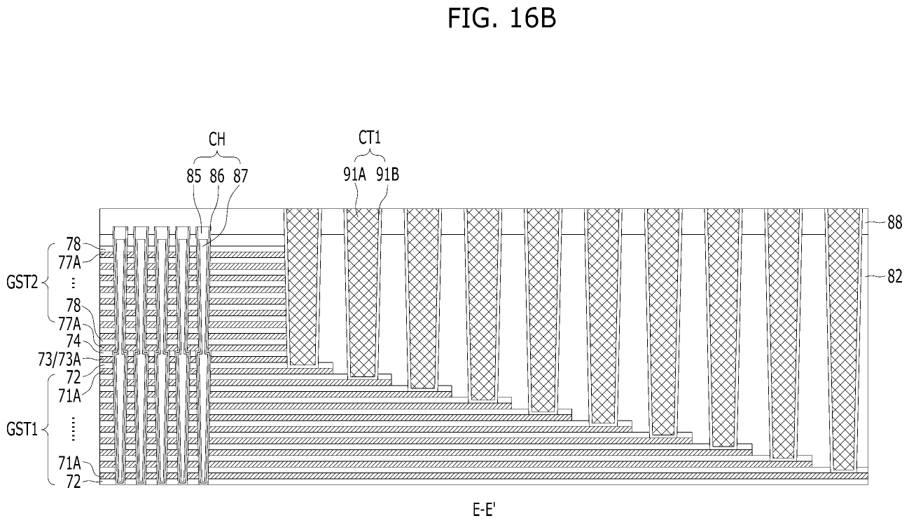

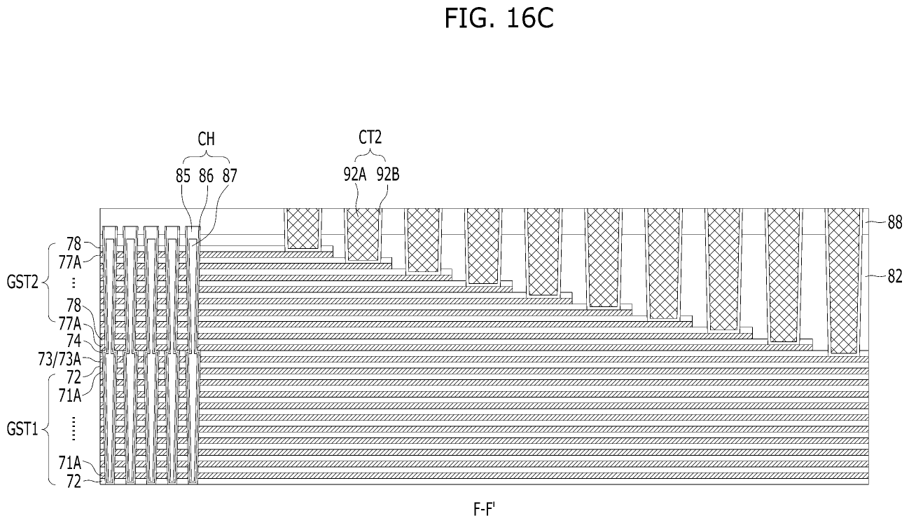

Referring to FIGS. 16A to 16C, the first and second contact plugs CT1 and CT2 may be formed. Each of the first contact plugs CT1 may be positioned between adjacent first supports SP1 or may be positioned between adjacent first supports SP1 and adjacent third supports SP3. Each of the second contact plugs CT2 may be positioned between adjacent second supports SP2. The first contact plug CT1 may include a first metal layer 91A and a first barrier layer 91B. The second contact plug CT2 may include a second metal layer 92A and a second barrier layer 92B.

According to the manufacturing method as described above, the second stack ST2 may be partially etched using the etch stop layer 73 to open the first contact region CTR1, thereby simultaneously forming the first step structure SS1 and the second step structure SS2 positioned at different levels. An etching process may be improved by dividing the second opening OP2 into the first sub-opening OP2A and the second sub-opening OP2B and forming the second opening OP2.

Although embodiments according to the technical concepts of the present disclosure have been described with reference to the accompanying drawings, these embodiments are only for describing examples according to the concepts of the present disclosure, and the present disclosure is not limited to the above-described embodiments. Within the scope of the technical concepts of the present disclosure, various substitutions, modifications, and changes of the embodiments will be possible by those skilled in the art to which the present disclosure belongs without departing from the scope of the present invention disclosure as defined in the appended claims. Furthermore, the embodiments may be combined to form additional embodiments.

What is claimed is:

1. A semiconductor device comprising:
a first gate structure including first gate lines each first gate line being exposed by a first step structure extending in a first direction;
a second gate structure disposed on the first gate structure to expose the first step structure and including second gate lines each second gate line being exposed by a second step structure extending in the first direction;
a channel structure extending through the first gate structure and the second gate structure, the channel structure having a first width;
a first support extending through the first step structure, the first support having a second width that is greater than the first width; and
a second support extending through the second step structure and the first gate structure, the second support having a third width that is greater than the first width.

2. The semiconductor device of claim 1, wherein the first width is a width of a top surface of the channel structure, the second width is a width of a top surface of the first support, and the third width is a width of a top surface of the second support.

3. The semiconductor device of claim 1, wherein the first step structure and the second step structure are adjacent to each other in a second direction crossing the first direction.

4. The semiconductor device of claim 1, wherein the first step structure and the second step structure are aligned in the second direction.

5. The semiconductor device of claim 1, further comprising:
first contact plugs positioned between the first supports and connected to the first gate lines, respectively; and
second contact plugs positioned between the second supports and connected to the second gate lines, respectively.

6. The semiconductor device of claim 1, wherein the channel structure includes a stepped sidewall, and the first support and the second support include a non-stepped sidewall.

7. The semiconductor device of claim 6, wherein the stepped sidewall of the channel structure includes a step difference positioned between the first gate structure and the second gate structure.

8. The semiconductor device of claim 1, wherein the channel structure and the second support include a stepped sidewall, and the first support includes a non-stepped sidewall.

9. The semiconductor device of claim 1, wherein the second width is greater than the third width.

10. The semiconductor device of claim 1, further comprising:
a third support positioned between the channel structure and the first support, extending through the second gate structure and the first gate structure, and having a fourth width greater than the first width and less than the second width.

11. The semiconductor device of claim 1, wherein at least one of the first support and the second support includes a dummy channel layer.

12. A semiconductor device comprising:
a first gate structure including first gate lines each exposed by a first step structure extending in a first direction;
a second gate structure disposed on the first gate structure to expose the first step structure and including second gate lines each exposed by a second step structure extending in the first direction;
an etch stop layer positioned between the first gate structure and the second gate structure to expose the first step structure;
a channel structure extending through the first gate structure, the etch stop layer, and the second gate structure, and including a stepped sidewall;
a first support extending through the first step structure and including a non-stepped sidewall; and
a second support extending through the second step structure, the etch stop layer, and the first gate structure.

13. The semiconductor device of claim 12, wherein the first step structure and the second step structure are aligned in a second direction crossing the first direction.

14. The semiconductor device of claim 12, wherein the channel structure has a first width, the first support has a second width greater than the first width, and the second support has a third width greater than the first width.

15. The semiconductor device of claim 14, wherein the first width is a width of a top surface of the channel structure, the second width is a width of a top surface of the first support, and the third width is a width of a top surface of the second support.

16. The semiconductor device of claim 14, wherein the second width is greater than the third width.
